(19) United States
(12) Patent Application Publication
(10) Pub. No.: US 2026/0182295 A1
(43) Pub. Date: Jun. 25, 2026

(54) BONDING APPARATUS, BONDING METHOD, AND METHOD FOR MANUFACTURING SEMICONDUCTOR DEVICE

(71) Applicant: Kioxia Corporation, Tokyo (JP)

(72) Inventor: Yoshio MIZUTA, Yokkaichi Mie (JP)

(73) Assignee: Kioxia Corporation, Tokyo (JP)

(21) Appl. No.: 19/238,173

(22) Filed: Jun. 13, 2025

(30) Foreign Application Priority Data
Dec. 20, 2024 (JP) 2024-224655

(51) Int. Cl. H01L 21/67; H01L 21/66; H01L 21/68

(52) U.S. Cl. CPC H10P 72/0438; H10P 72/50; H10P 74/203

(57) ABSTRACT

According to one embodiment, a bonding apparatus includes first and second stages. The first stage includes stage pins. The first stage holds a first substrate by using the stage pins. The second stage holds a second substrate. The first stage has a center portion and an outer peripheral portion. The stage pins include first pins arranged in a first direction. The first pins are configured such that at least one of an area and a length is different between a first pin located in the center portion and a first pin located in the outer peripheral portion. The stage pins include second pins arranged in a second direction. The second pins are configured such that at least one of an area and a length is substantially the same between the second pin located in the center portion and the second pin located in the outer peripheral portion.

### CROSS-REFERENCE TO RELATED APPLICATIONS

This application is based upon and claims the benefit of priority from Japanese Patent Application No. 2024-224655, filed Dec. 20, 2024, the entire contents of which are incorporated herein by reference.

### FIELD

Embodiments described herein relate generally to a bonding apparatus, a bonding method, and a method for manufacturing a semiconductor device.

### BACKGROUND

A three-dimensional stacking technique for three-dimensionally stacking semiconductor circuit substrates is known.

### BRIEF DESCRIPTION OF THE DRAWINGS

FIG. 1 is a schematic diagram showing an outline of a method for manufacturing a semiconductor device.

FIG. 2 is a schematic diagram showing an example of arrangement of alignment marks used in a manufacturing process of a semiconductor device.

FIG. 3 is a table showing an example of correction performance of an exposure apparatus and a bonding apparatus for overlay components in a wafer plane that can remain in bonding overlay.

FIG. 4 is a block diagram showing an example of a configuration of a semiconductor manufacturing system according to a first embodiment.

FIG. 5 is a block diagram showing an example of a configuration of an exposure apparatus included in the semiconductor manufacturing system according to the first embodiment.

FIG. 6 is a block diagram showing an example of a configuration of a bonding apparatus included in the semiconductor manufacturing system according to the first embodiment.

FIG. 7 is a schematic diagram showing an example of a configuration of a lower stage included in the bonding apparatus according to the first embodiment.

FIG. 8 is a plan view showing an example of a planar layout of the lower stage in a first configuration example of the bonding apparatus according to the first embodiment.

FIG. 9 is a cross-sectional view taken along line IX-IX of FIG. 8, showing an example of a cross-sectional structure along an X direction of the lower stage in the first configuration example of the bonding apparatus according to the first embodiment.

FIG. 10 is a cross-sectional view taken along line X-X of FIG. 8, showing an example of a cross-sectional structure along a Y direction of the lower stage in the first configuration example of the bonding apparatus according to the first embodiment.

FIG. 11 is a plan view showing an example of a planar layout of the lower stage in a second configuration example of the bonding apparatus according to the first embodiment.

FIG. 12 is a cross-sectional view taken along line XII-XII of FIG. 11, showing an example of a cross-sectional structure along the X direction of the lower stage in the second configuration example of the bonding apparatus according to the first embodiment.

FIG. 13 is a cross-sectional view taken along line XIII-XIII of FIG. 11, showing an example of a cross-sectional structure along the Y direction of the lower stage in the second configuration example of the bonding apparatus according to the first embodiment.

FIG. 14 is a plan view showing an example of a planar layout of the lower stage in a third configuration example of the bonding apparatus according to the first embodiment.

FIG. 15 is a cross-sectional view taken along line XV-XV of FIG. 14, showing an example of a cross-sectional structure along the X direction of the lower stage in the third configuration example of the bonding apparatus according to the first embodiment.

FIG. 16 is a cross-sectional view taken along line XVI-XVI of FIG. 14, showing an example of a cross-sectional structure along the Y direction of the lower stage in the third configuration example of the bonding apparatus according to the first embodiment.

FIG. 17 is a block diagram showing an example of a configuration of a server included in the semiconductor manufacturing system according to the first embodiment.

FIG. 18 is a schematic diagram showing an outline of a bonding process in the bonding apparatus according to the first embodiment.

FIG. 19 is a schematic diagram showing how heat is transferred to a lower wafer held by the lower stage included in the bonding apparatus according to the first embodiment.

FIG. 20 is a graph showing a first example of temperature change of the lower wafer held by the lower stage included in the bonding apparatus according to the first embodiment.

FIG. 21 is a graph showing a second example of temperature change of the lower wafer held by the lower stage included in the bonding apparatus according to the first embodiment.

FIG. 22 is a diagram describing influence of thermal expansion of the lower stage in the bonding apparatus according to the first embodiment.

FIG. 23 is a flowchart showing an example of a method of learning wafer magnification correction values in the semiconductor manufacturing system according to the first embodiment.

FIG. 24 is a graph showing an example of a result of learning of wafer magnification correction values in the semiconductor manufacturing system according to the first embodiment.

FIG. 25 is a flowchart showing a first example of a bonding method of the bonding apparatus according to the first embodiment.

FIG. 26 is a flowchart showing a second example of a bonding method of the bonding apparatus according to the first embodiment.

FIG. 27 is a flowchart showing an example of a method of learning wafer magnification correction values in a semiconductor manufacturing system according to a second embodiment.

FIG. 28 is a graph showing an example of a result of learning of wafer magnification correction values in the semiconductor manufacturing system according to the second embodiment.

FIG. 29 is a block diagram showing an example of an overall configuration of a memory device according to a third embodiment.

FIG. 30 is a circuit diagram showing an example of a circuit configuration of a memory cell array included in the memory device according to the third embodiment.

FIG. 31 is a perspective view showing an example of a structure of the memory device according to the third embodiment.

FIG. 32 is a plan view showing an example of a planar layout of the memory cell array included in the memory device according to the third embodiment.

FIG. 33 is a cross-sectional view showing an example of a cross-sectional structure of the memory cell array included in the memory device according to the third embodiment.

FIG. 34 is a cross-sectional view taken along line XXXIV-XXXIV of FIG. 33, showing an example of a cross-sectional structure of a memory pillar included in the memory device according to the third embodiment.

FIG. 35 is a cross-sectional view showing an example of a cross-sectional structure of the memory device according to the third embodiment.

### DETAILED DESCRIPTION

In general, according to one embodiment, a bonding apparatus, includes: a first stage including a body part, a plurality of stage pins provided on an upper portion of the body part, and a heater that heats the body part, the first stage being configured to be able to hold a first substrate by using the stage pins; a second stage configured to be able to hold a second substrate; and a processor configured to control the first stage and the second stage to execute bonding process of bonding the first substrate and the second substrate. The first stage has, in a planar view, a center portion including a center of the first stage and an outer peripheral portion located on an outer periphery of the center portion. The stage pins include a plurality of first pins arranged in a first direction. The plurality of first pins are configured such that at least one of an area and a length is different between a first pin located in the center portion of the first stage and a first pin located in the outer peripheral portion. The stage pins include a plurality of second pins arranged in a second direction different from the first direction. The plurality of second pins are configured such that at least one of the area and the length is substantially the same between a second pin located in the center portion of the first stage and a second pin located in the outer peripheral portion.

Hereinbelow, embodiments are described with reference to the drawings. Each embodiment gives examples of a device and a method for embodying the technical idea of the invention. The drawings are schematic or conceptual. Dimensions, ratios, and the like of each drawing are not necessarily the same as the actual dimensions, ratios, and the like. Where appropriate, illustrations of configurations are omitted. In the present specification, constituent elements having substantially the same functions and configurations have the same reference signs assigned thereto. Numerals and the like appended to the reference signs are referred to using the same reference signs and are used to distinguish between similar elements.

In the following, two directions intersecting each other are referred to as an “X direction” and a “Y direction”, and a plane parallel to the X direction and the Y direction is referred to as an “XY plane”. In the following description, a direction perpendicular to the XY plane is referred to as a “Z direction”. In the present specification, “above” means vertically above with respect to a component as a reference. In the present specification, “below” means vertically below with respect to a component as a reference. In the present specification, a “planar view” means that a component such as a horizontally mounted layer is visually recognized from above, for example. “Visual recognition” includes observing an object by using a microscope, a camera, or the like.

The semiconductor device in the present specification is formed by bonding two semiconductor circuit substrates each with a semiconductor circuit formed thereon and separating the bonded semiconductor circuit substrates on a chip basis. Hereinafter, the semiconductor circuit substrate is referred to as a “wafer”. The process for bonding two wafers is referred to as a “bonding process”. An apparatus that executes the bonding process is referred to as a “bonding apparatus”. The wafers arranged on the upper side and the lower side during the bonding process are referred to as an “upper wafer UW” and a “lower wafer LW”, respectively. A set of the upper wafer UW and the lower wafer LW bonded is referred to as a “bonded wafer BW”. The “front surface of the wafer” corresponds to a surface on the side on which a semiconductor circuit is formed by a front-end process. The “back surface of the wafer” corresponds to a surface on the opposite side to the front surface of the wafer.

### <0> Outline of a Method for Manufacturing a Semiconductor Device

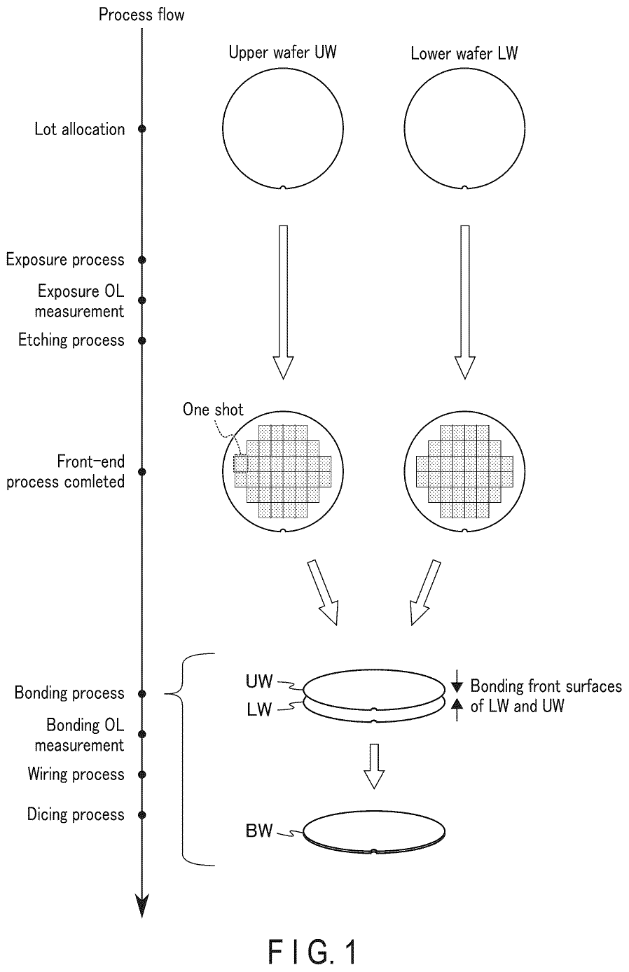

FIG. 1 is a schematic diagram showing an outline of a method for manufacturing a semiconductor device. A rough process flow of a method for manufacturing a semiconductor device will now be described with reference to FIG. 1.

First, wafers are allocated to a lot (“lot allocation”). A lot may include a plurality of wafers. The Lot is categorized into, for example, a lot including upper wafers UW and a lot including lower wafers LW. Each upper wafer UW is associated with one lower wafer LW.

Then, a front-end process is performed on each of the lot including upper wafers UW and the lot including lower wafers LW. The front-end process includes a combination of “exposure process”, “exposure OL (overlay) measurement”, and “etching process”. Although a description is omitted in the present specification, the front-end process can include a heating step, a cleaning step, a film formation step, etc.

The exposure process is a process of transferring a pattern of a mask (reticle) to a resist material on the wafer in units of shots. The “shot” corresponds to a partition area of exposure in the exposure process. The arrangement of shots of the upper wafer UW and the arrangement of shots of the lower wafer LW are set to be identical. In the exposure process, one-shot exposure is repeatedly executed with the exposure position shifted. That is, an exposure apparatus exposes the wafer by a step-and-repeat method. After that, parts of the resist material are removed by development process, and a desired pattern is transferred to the resist material. In the exposure process, the arrangement and shape of shots are corrected based on a result of measurement of alignment marks, various correction values, etc. Thereby, the overlay positions of the pattern of the ground layer and the pattern formed by the exposure process are adjusted (aligned).

The exposure OL measurement is a process of measuring the amount of overlay deviation of the pattern of the ground layer and the pattern of the resist material formed by the exposure process. The measurement result obtained by exposure OL measurement is used to, for example, perform determination of rework of the exposure process, calculate an alignment correction value to be applied to the following lot, etc.

The etching process is a process of machining a member on the wafer by using the resist material formed by the exposure process as a mask. By etching process, the member on the wafer is processed into a configuration based on the pattern of the resist material. The circuit pattern for each layer can be formed by a combination of such exposure process and etching process.

By the front-end process of the upper wafer UW being performed, a desired semiconductor circuit is formed on the front surface of the upper wafer UW. By the front-end process of the lower wafer LW being performed, a desired semiconductor circuit is formed on the front surface of the lower wafer LW (“Front-end process comleted”). After that, the bonding process is executed using the associated set of the upper wafer UW and the lower wafer LW.

In the bonding process, a bonding apparatus holds the front surface of the upper wafer UW and the front surface of the lower wafer LW while setting them facing each other. Then, the bonding apparatus adjusts (aligns) the overlay positions of the pattern formed on the front surface of the upper wafer UW and the pattern formed on the front surface of the lower wafer LW based on a result of measurement of alignment marks. Then, the bonding apparatus brings the front surface of the upper wafer UW and the front surface of the lower wafer LW into contact with each other. Thereby, the front surface of the upper wafer UW and the front surface of the lower wafer LW are bonded, and a bonded wafer BW is formed. After that, bonding OL (overlay) measurement is executed on the bonded wafer BW.

The bonding OL measurement is a process of measuring the amount of overlay deviation of the pattern formed on the bonding surface of the upper wafer UW and the pattern formed on the bonding surface of the lower wafer LW. The “bonding layer” corresponds to a layer in contact with a boundary portion between the upper wafer UW and the lower wafer LW. Each of the upper wafer UW and the lower wafer LW has a bonding layer. The measurement result obtained by bonding OL measurement can be used to calculate an alignment correction value to be applied to the exposure process of the following lot, etc.

After that, an wiring process is performed on the bonded wafer BW, and interconnects (wirings) and pads used for external connection to a circuit provided on the bonded wafer BW are formed. Then, the bonded wafer BW is separated on a chip basis by a dicing process; thus, a plurality of semiconductor devices are formed from one bonded wafer BW.

In the present specification, alignment is adapted to the shape of the wafer in the standard of the exposure apparatus or the bonding apparatus. The amount of overlay deviation corresponds to misalignment between the pattern of the overlay source and the pattern of the overlay destination. That is, a component that cannot be corrected by the exposure process or the bonding process based on the result of alignment measurement causes overlay deviation. In the following, a correction value used in alignment of overlay positions is referred to as an “alignment correction value”. In a case where a polynomial is used to correct alignment, the coefficient of each term is referred to as an “alignment correction coefficient”. That is, the alignment correction values can be calculated based on the alignment correction coefficient for each term and the exposure position.

The amount of overlay deviation that can occur in each of the exposure process and the bonding process can be expressed by a combination of various components. For example, a result of overlay (alignment) measurement is broken down on a K value basis by polynomial regression. Overlay components expressed by K values include an offset (shift) component, a magnification component, and an orthogonality component. Formulae corresponding to the components are listed hereinbelow. In the following mathematical formulae, “x” and “y” correspond to the coordinate in the X direction (the X coordinate) and the coordinate in the Y direction (the Y coordinate), respectively. “dx” and “dy” correspond to the amounts of overlay deviation in the X direction and the Y direction, respectively. “K1” to “K6” correspond to alignment correction coefficients (polynomial regression coefficients).

An offset (shift) component in the X direction is “dx=K1”.

The offset (shift) component in the Y direction is “dy=K2”.

The magnification component in the X direction is “dx=K3·x”.

The magnification component in the Y direction is “dy=K4·y”.

An orthogonality component in the X direction is “dx=K5·y”.

The orthogonality component in the Y direction: “dy=K6·x”.

In the present example, the amount of overlay deviation in the X direction Ex is calculated by “Ex=K1+K3·x+K5·y”. The amount of overlay deviation in the Y direction Ey is calculated by “Ey=K2+K4·y+K6·x”. In a case where overlay components are expressed by polynomial regression, not only K1 to K6 but also a coefficient assigned to a higher-order overlay component may be used as a polynomial regression coefficient. The amount of overlay deviation described above can be calculated in units of shots and in the plane of the wafer. In the following, the overlay component of a magnification component generated in the plane of the wafer is referred to also as a “wafer magnification component”. The wafer magnification component corresponds to the size of the wafer. An overlay component randomly generated in the wafer plane is referred to as a “random component”.

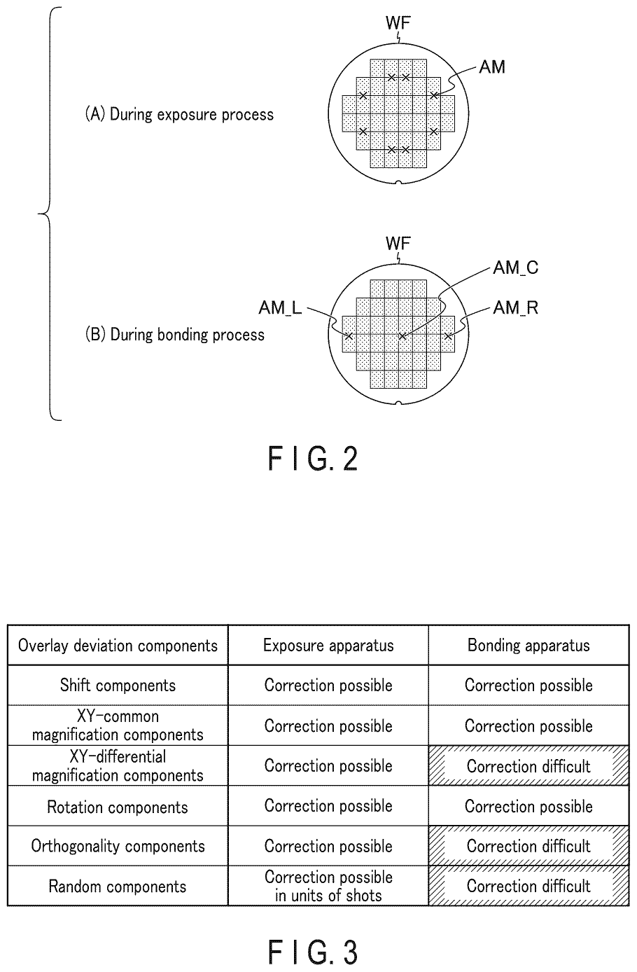

FIG. 2 is a schematic diagram showing an example of arrangement of alignment marks AM used in the manufacturing process of a semiconductor device. (A) of FIG. 2 shows an example of arrangement of a plurality of alignment marks AM on a wafer WF that are measured during the exposure process. (B) of FIG. 2 shows an example of arrangement of a plurality of alignment marks AM on the wafer WF that are measured during the bonding process.

As shown in (A) of FIG. 2, during the exposure process, the exposure apparatus measures multiple alignment marks AM arranged on the wafer WF (that is, the upper wafer UW or the lower wafer LW). The number of alignment marks AM measured is preferably three or more. The exposure apparatus may subject the result of measurement of multiple alignment marks AM to function approximation with an orthogonal coordinate system, and can thereby calculate alignment correction values such as shift components, magnification components, and orthogonality components in the X direction and the Y direction. Further, based on the result of measurement of multiple alignment marks AM, the exposure apparatus can correct each of overlay in units of shots and overlay in the plane of the wafer.

As shown in (B) of FIG. 2, during the bonding process, the bonding apparatus measures, for example, three alignment marks AM_C, AM_L, and AM_R arranged on each of the upper wafer UW and the lower wafer LW. Alignment mark AM_C is located at the center of the wafer. Alignment marks AM_L and AM_R are located on one side and the other side of the outer periphery of the wafer WF, respectively. Based on the result of measurement of alignment marks AM_C, AM_L, and AM_R of each of the upper wafer UW and the lower wafer LW, the bonding apparatus can calculate alignment correction values to shift components and rotation components. Like the exposure apparatus, the bonding apparatus may be configured to be able to measure multiple alignment marks AM and calculate wafer magnification components.

FIG. 3 is a table showing an example of correction performance of an exposure apparatus and a bonding apparatus for overlay components in a wafer plane that can remain in bonding overlay. As shown in FIG. 3, the XY difference of wafer magnification components (XY-differential magnification components) can be corrected in the exposure apparatus, but is difficult to correct in the bonding apparatus.

### <1> First Embodiment

A first embodiment relates to a bonding apparatus, a bonding method, and a method for manufacturing a semiconductor device capable of improving the XY difference of wafer magnification components between the upper wafer UW and the lower wafer LW during the bonding process.

### <1-1> Configuration

A configuration of a semiconductor manufacturing system PS according to the first embodiment will now be described.

### <1-1-1> Configuration of the Semiconductor Manufacturing System PS

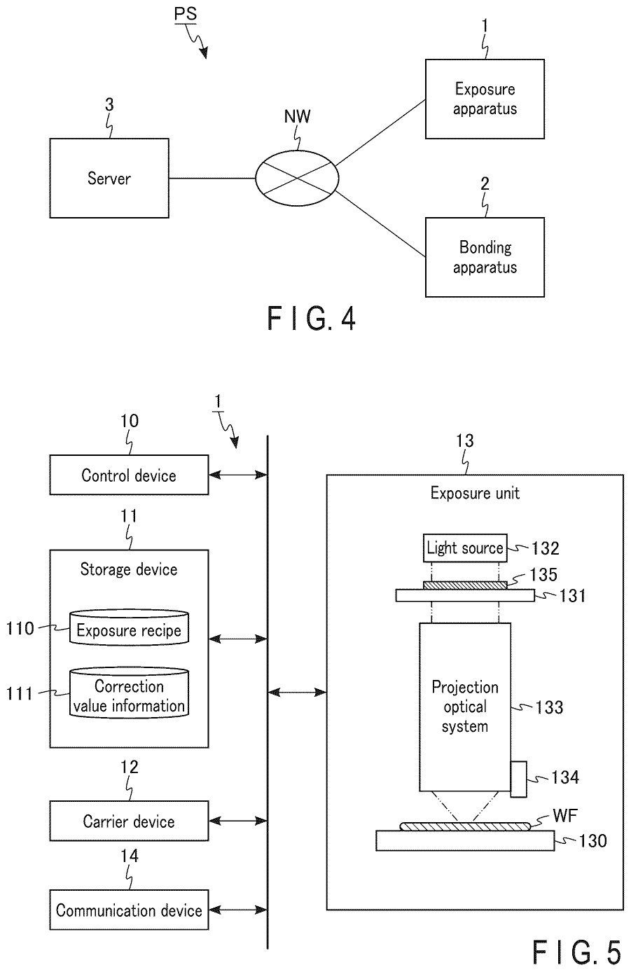

FIG. 4 is a block diagram showing an example of a configuration of the semiconductor manufacturing system PS according to the first embodiment. As shown in FIG. 4, the semiconductor manufacturing system PS includes, for example, an exposure apparatus 1, a bonding apparatus 2, and a server 3. The exposure apparatus 1, the bonding apparatus 2, and the server 3 are configured to be capable of communicating via a network NW. Wired communication or wireless communication may be used for the network NW. The bonding apparatus 2 executes the bonding process by using the upper wafer UW and the lower wafer LW for which the exposure apparatus 1 was used in a front-end process, and produces a bonded wafer BW. The server 3 is, for example, a computer or the like that controls the entire manufacturing process of a semiconductor device. The server 3 manages correction values, etc. used in a lot processing step and various manufacturing steps. Note that the semiconductor manufacturing system PS can also include an overlay measurement device or the like.

### <1-1-2> Configuration of the Exposure Apparatus 1

FIG. 5 is a block diagram showing an example of a configuration of the exposure apparatus 1 included in the semiconductor manufacturing system PS according to the first embodiment. As shown in FIG. 5, the exposure apparatus 1 includes, for example, a control device 10, a storage device 11, a carrier device 12, an exposure unit 13, and a communication device 14.

The control device 10 is a computer or the like that controls the entire operation of the exposure apparatus 1. The control device 10 controls each of the storage device 11, the carrier device 12, the exposure unit 13, and the communication device 14. Although illustration is omitted, the control device 10 includes a CPU (central processing unit), a ROM (read-only memory), a RAM (random-access memory), etc. The CPU is a processor that executes various programs relating to the control of devices. The ROM is a nonvolatile storage medium that stores a device control program. The RAM is a volatile storage medium that is used as a work area of the CPU.

The storage device 11 is a storage medium used to store data, programs, etc. The storage device 11 stores, for example, an exposure recipe 110 and correction value information 111. The exposure recipe 110 is a table in which the setting of the exposure process is recorded. The exposure recipe 110 includes information such as the shape and layout of shots, the amount of exposure, the setting of focus, and the setting of alignment. The exposure recipe 110 can be prepared for each processing step or each lot. The correction value information 111 is a log that records alignment correction values (that is, alignment results) used during execution of the exposure process.

The carrier device 12 is a device including a conveyance arm capable of conveying a wafer, a transition for temporarily mounting a plurality of wafers, etc. For example, the carrier device 12 conveys the wafer WF received from an external coating-development device to the exposure unit 13. Further, after the exposure process, the carrier device 12 conveys the wafer WF received from the exposure unit 13 to the outside of the exposure apparatus 1. The “coating-development device” is a device that executes pre-process and post-process of the exposure process. The pre-process of the exposure process includes a process for coating the wafer with a resist material (photosensitive material). The post-process of the exposure process includes a process for developing a pattern with which the wafer is exposed. As devices used in the pre-process and the post-process of the exposure process, a plurality of semiconductor manufacturing devices may be used.

The exposure unit 13 is a set of constituent elements used in the exposure process. The exposure unit 13 includes, for example, a wafer stage 130, a reticle stage 131, a light source 132, a projection optical system 133, and a camera 134. The wafer stage 130 has a function of holding a wafer WF. The reticle stage 131 has a function of holding a reticle 135 (mask). The stage positions of the wafer stage 130 and the reticle stage 131 can be controlled based on the control of the control device 10. The light source 132 irradiates the reticle 135 with generated light. The projection optical system 133 condenses light transmitted through the reticle 135 onto a surface of the wafer WF. The camera 134 is a photographing mechanism used to measure an alignment mark AM.

The communication device 14 is a communication interface capable of connecting to the network NW. The exposure apparatus 1 may operate based on an operation by a terminal on the network, or may store the exposure recipe 110 and the correction value information 111 in a server on the network.

### <1-1-3> Configuration of the Bonding Apparatus 2

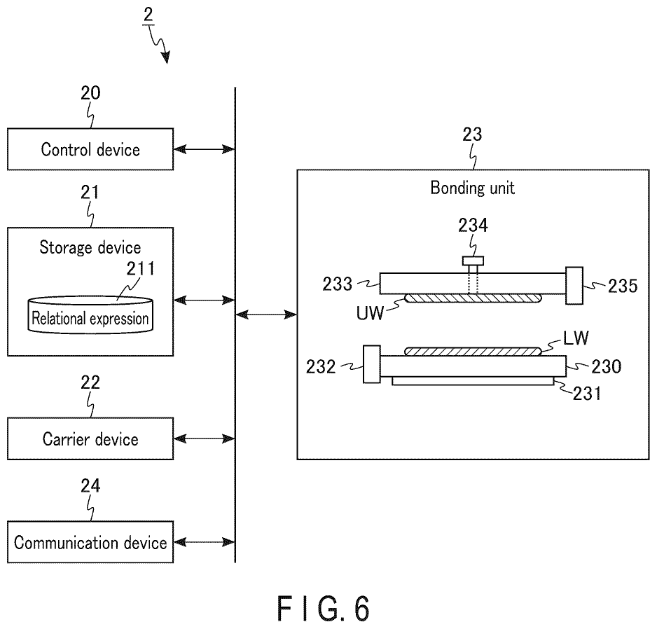

FIG. 6 is a block diagram showing an example of a configuration of the bonding apparatus 2 included in the semiconductor manufacturing system PS according to the first embodiment. As shown in FIG. 6, the bonding apparatus 2 includes, for example, a control device 20, a storage device 21, a carrier device 22, a bonding unit 23, and a communication device 24.

The control device 20 is a computer or the like that controls the entire operation of the bonding apparatus 2. The control device 20 controls each of the storage device 21, the carrier device 22, the bonding unit 23, and the communication device 24. Although illustration is omitted, the control device 20 includes a CPU, a ROM, a RAM, etc. The control device 20 may be referred to as a processor.

The storage device 21 is a storage medium used to store data, programs, etc. The storage device 21 stores, for example, a relational expression 211. The relational expression 211 is a mathematical formula used to, during the bonding process of the lower wafer LW and the upper wafer UW, correct the XY difference of wafer magnification components between the lower wafer LW and the upper wafer UW. Details of the relational expression 211 will be described later.

The carrier device 22 is a device including a conveyance arm capable of conveying a wafer, a transition for temporarily mounting a plurality of wafers, etc. For example, the carrier device 22 conveys the upper wafer UW and the lower wafer LW received from a pre-process device for the bonding process to the bonding unit 23. Further, after the bonding process, the carrier device 22 conveys the bonded wafer BW received from the bonding unit 23 to the outside of the bonding apparatus 2. The carrier device 22 may include a mechanism that vertically inverts the wafer.

The bonding unit 23 is a set of constituent elements used in the bonding process. The bonding unit 23 includes, for example, a lower stage 230, a stress device 231, a camera 232, an upper stage 233, a pushpin 234, and a camera 235. The lower stage 230 is, for example, a wafer stage having a function as a wafer chuck that holds the lower wafer LW by vacuum suction. The stress device 231 has a function of applying stress to the lower stage 230 and deforming the lower wafer LW via the lower stage 230. The amount of expansion (scaling) of the lower wafer LW held by the lower stage 230 changes according to the amount of deformation of the lower stage 230 by the stress device 231. The camera 232 is a photographing mechanism placed on the lower stage 230 side and used to measure an alignment mark AM of the upper wafer UW. The upper stage 233 is, for example, a wafer stage having a function as a wafer chuck that holds the upper wafer UW by vacuum suction. The pushpin 234 is a pin that can be driven in the up-down direction based on the control of the control device 20 to press the upper surface of a center portion of the upper wafer UW held by the upper stage 233. The camera 235 is a photographing mechanism placed on the upper stage 233 side and used to measure an alignment mark AM of the lower wafer LW. The bonding apparatus 2 may include a vacuum pump used in vacuum suction of the lower stage 230 and the upper stage 233.

The lower stage 230 and the upper stage 233 are configured such that the lower wafer LW held by the lower stage 230 and the upper wafer UW held by the upper stage 233 can be arranged to face each other. In the bonding process, the upper surface of the upper wafer UW is the back surface of the upper wafer UW, and is held by the upper stage 233 of the bonding apparatus 2. In the bonding process, the lower surface of the upper wafer UW is the front surface of the upper wafer UW, and corresponds to the bonding surface. The upper surface of the lower wafer LW is the front surface of the lower wafer LW, and corresponds to the bonding surface. The lower surface of the lower wafer LW is the back surface of the lower wafer LW, and is held by the lower stage 230 of the bonding apparatus 2. By adjusting the relative positions of the lower stage 230 and the upper stage 233, the bonding apparatus 2 can adjust a shift component and a rotation component of overlay deviation. Further, by using the stress device 231 to deform the lower stage 230, the bonding apparatus 2 can adjust a wafer magnification component common to X and Y of the lower wafer LW held by the deformed lower stage 230. Further, by adjusting the temperature of the lower stage 230, the bonding apparatus 2 can adjust an XY difference of wafer magnification components of the lower wafer LW.

The communication device 24 is a communication interface capable of connecting to the network NW. The bonding apparatus 2 may operate based on the control of a terminal on the network NW, may store an operation log in the server 3 on the network NW, or may calculate an alignment correction value based on information stored in the server 3.

The above “pre-process device for the bonding process” is a device having a function of, before the bonding process by the bonding apparatus 2, modifying and hydrophilizing the bonding surfaces of the upper wafer UW and the lower wafer LW so that both bonding surfaces can be bonded. To put it briefly, the pre-process device first executes plasma treatment on the surfaces of the upper wafer UW and the lower wafer LW, and modifies the surfaces of the upper wafer UW and the lower wafer LW. In the plasma process, oxygen ions or nitrogen ions are generated based on oxygen gas or nitrogen gas serving as the treatment gas, under a predetermined reduced atmosphere, and the generated oxygen ions or nitrogen ions are applied to the bonding surface of each wafer. Thereafter, the pre-process device supplies pure water to the respective surfaces of the upper wafer UW and the lower wafer LW. Thereupon, hydroxyl groups adhere to the respective surfaces of the upper wafer UW and the lower wafer LW, and the surfaces are hydrophilized. In the bonding process, the upper wafer UW and the lower wafer LW, the bonding surfaces of which have been modified and hydrophilized as described above, are used. The bonding apparatus 2 may be combined with the pre-process device, etc. to form a bonding system.

### (Overview of a Structure of the Lower Stage 230)

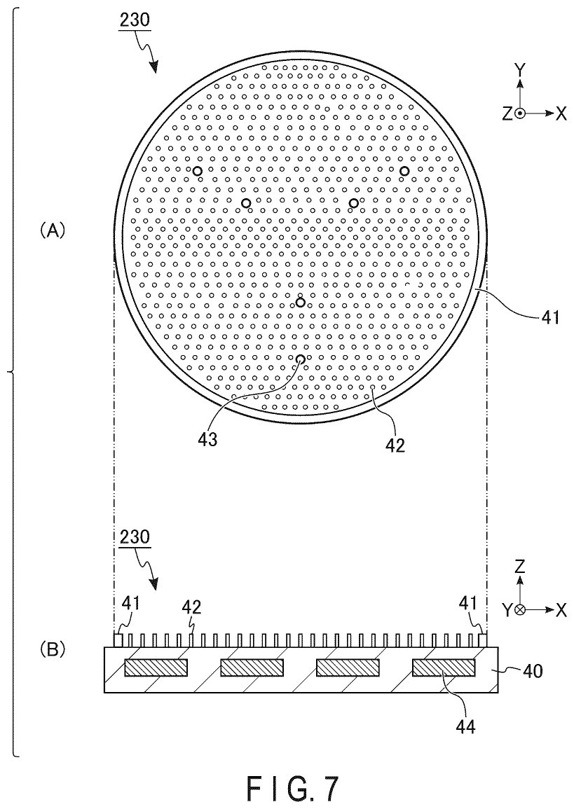

FIG. 7 is a schematic diagram showing an example of a configuration of the lower stage 230 included in the bonding apparatus 2 according to the first embodiment. (A) of FIG. 7 shows a planar layout of the lower stage 230 in the first embodiment. (B) of FIG. 7 shows a cross-sectional structure of the lower stage 230 in the first embodiment. As shown in FIG. 7, the lower stage 230 includes a body part 40, a rib 41, a plurality of stage pins 42, a plurality of suction ports 43, and a heater 44.

The diameter of the body part 40 is larger than at least the diameter of the lower wafer LW in a planar view. The rib 41 and the stage pins 42 are provided on the upper surface of the body part 40. The upper surface of the body part 40 corresponds to the suction surface of the wafer chuck. The heights of the rib 41 and the stage pins 42 are substantially equal. In other words, the positions (heights) of the upper surfaces of the rib 41 and the stage pins 42 are aligned. The rib 41 is provided in a ring shape, and is placed in an outer peripheral portion of the wafer chuck portion of the lower stage 230. The stage pins 42 are arranged apart from each other on the inside of the rib 41 in a planar view.

The suction ports 43 are arranged apart from each other on the inside of the rib 41 in a planar view. Each suction port 43 is connected to a not-illustrated vacuum pump. In a case where the wafer WF is placed on the lower stage 230, the vacuum pump can, via the suction ports 43, decompress the space surrounded by the upper surface of the body part 40, the rib 41, and the wafer WF. In a case where the space surrounded by the upper surface of the body part 40, the rib 41, and the wafer WF is depressurized, based on the fact that the outside atmosphere is, for example, atmospheric pressure, the lower wafer LW is sucked to the lower stage 230 side and held. In a case where the lower wafer LW is sucked, the rib 41 supports an outer peripheral portion of the lower surface of the lower wafer LW, and each of the stage pins 42 supports part of the lower surface of the lower wafer LW. By the lower surface of the lower wafer LW being supported by the stage pins 42, the lower wafer LW is held in a flat shape, and distortion (warpage) in the Z direction of the lower wafer LW can be suppressed.

The heater 44 has a function of heating the body part 40 based on the control of the control device 20. The heater 44 is desirably placed in the inside of the body part 40 such that the stage pins 42 arranged on the upper surface of the body part 40 can be heated substantially uniformly. The heater 44 may be divided and arranged in the body part 40. In a case where the body part 40 is heated by the heater 44, the heat of the body part 40 moves to the sucked lower wafer LW via the stage pins 42.

The shape of the lower stage 230 can be deformed according to the temperature of the lower stage 230 and the stress applied by the stress device 231. In this case, the lower wafer LW sucked by the lower stage 230 is deformed according to the deformation of the lower stage 230. Further, by using the stage pins 42 to support the lower wafer LW, the lower stage 230 can suppress the influence of particles remaining on the lower surface of the lower wafer LW on the flatness of the sucked lower wafer LW. Further, by using the stage pins 42, the contact area between the lower stage 230 and the lower wafer LW is reduced; thus, in a case where the suction of the lower wafer LW by the lower stage 230 is released, the lower wafer LW can be easily peeled off from the lower stage 230.

Further, in the bonding apparatus 2 according to the first embodiment, by utilizing the arrangement and shape of the stage pins 42 and the shape of the body part 40, the lower stage 230 is configured such that the way heat is transferred to the sucked lower wafer LW is non-uniform in the wafer plane. A first to a third configuration example of the lower stage 230 in the bonding apparatus 2 according to the first embodiment will now be described. In the drawings of the lower stage 230 used in the description of the first to third configuration examples, the illustration of the suction port 43 and the heater 44 is omitted, and characteristic portions are emphasized and illustrated.

### First Configuration Example

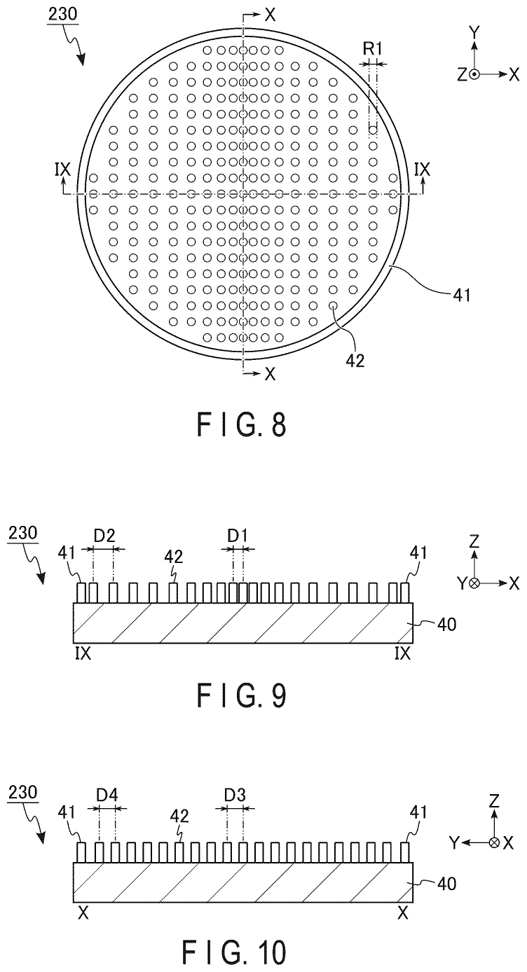

FIG. 8 is a plan view showing an example of a planar layout of the lower stage 230 in a first configuration example of the bonding apparatus 2 according to the first embodiment. As shown in FIG. 8, in the lower stage 230 of the first configuration example, the degree of denseness (density) of the number of stage pins 42 is provided to change in one direction. For example, the stage pins 42 are provided such that, in the X direction, the degree of denseness decreases from a center portion toward an outer peripheral portion of the lower stage 230 (the body part 40). On the other hand, in the Y direction, the stage pins 42 are, for example, provided at equal intervals. Although FIG. 8 shows, as an example, a case where a plurality of stage pins 42 are arranged in a lattice pattern, the stage pins 42 may not be arranged in a lattice pattern. In the first configuration example, the widths and sizes of the stage pins 42 are substantially equal.

FIG. 9 is a cross-sectional view taken along line IX-IX of FIG. 8, showing an example of a cross-sectional structure along the X direction of the lower stage 230 in the first configuration example of the bonding apparatus 2 according to the first embodiment. In the first configuration example, the pitch of stage pins 42 arranged in the X direction is, for example, in the range of 2000 to 20000 μm. Specifically, as shown in FIG. 9, in the center portion of the lower stage 230, the pitch D1 between two stage pins 42 adjacent in the X direction is, for example, 2000 μm. In the outer peripheral portion of the lower stage 230, the pitch D2 between two stage pins 42 adjacent in the X direction is, for example, 20000 μm.

FIG. 10 is a cross-sectional view taken along line X-X of FIG. 8, showing an example of a cross-sectional structure along the Y direction of the lower stage 230 in the first configuration example of the bonding apparatus 2 according to the first embodiment. In the first configuration example, the pitch of stage pins 42 arranged in the Y direction is, for example, a fixed value. Specifically, as shown in FIG. 10, the pitch D3 between two stage pins 42 adjacent in the Y direction in the center portion of the lower stage 230 is substantially equal to the pitch D4 between two stage pins 42 adjacent in the Y direction in the outer peripheral portion of the lower stage 230. Each of the pitches D3 and D4 is, for example, 10000 μm. Therefore, the pitches of the stage pins 42 have relationships of D2>D3=D4>D1.

It is sufficient that the lower stage 230 of the first configuration example be designed such that, in the X direction, the ratio of the area of the places where the lower wafer LW and the stage pins 42 are in contact decreases from the center portion toward the outer peripheral portion of the lower stage 230. In the lower stage 230 of the first configuration example, the ratio of the area of the places where the lower wafer LW and the stage pins 42 are in contact is preferably in the range of 1 to 25%. For example, the ratio of the area of the upper surfaces of the stage pins 42 (that is, the places where the stage pins 42 and the lower wafer LW are in contact) in the center portion of the lower stage 230 is 25%, and the ratio of the area of the upper surfaces of the stage pins 42 in the outer peripheral portion of the lower stage 230 is 18. In other words, in the lower stage 230 of the first configuration example, the contact area between the lower wafer LW and the stage pins 42 in a 1-cm² area at the time of suction of the lower wafer LW is 0.25 cm² (that is, the contact ratio=25%) in the center portion and 0.01 cm² (that is, the contact ratio=1%) in the outer peripheral portion.

### Second Configuration Example

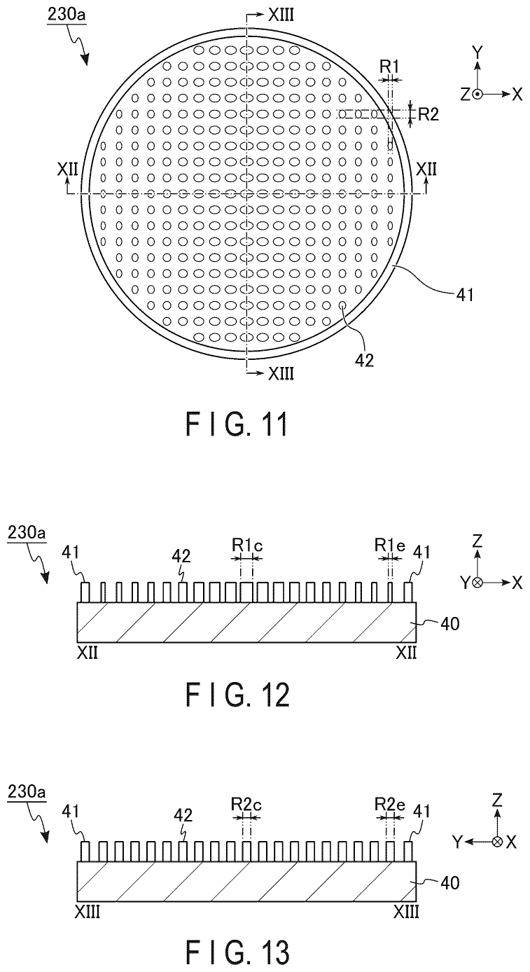

FIG. 11 is a plan view showing an example of a planar layout of a lower stage 230a in a second configuration example of the bonding apparatus 2 according to the first embodiment. As shown in FIG. 11, in the lower stage 230a of the second configuration example, a plurality of stage pins 42 are arranged such that the size changes in one direction. Here, the “size of the stage pin 42” corresponds to the area of the upper surface of the stage pin 42, that is, the area of the contact portion between the stage pin 42 and the lower wafer LW in a case where the lower wafer LW is sucked to the lower stage 230a.

For example, the size of the stage pin 42 included in the stage pins 42 arranged in the X direction decreases from a center portion toward an outer peripheral portion of the lower stage 230a (the body part 40). On the other hand, the sizes of the stage pins 42 included in the stage pins 42 arranged in the Y direction are, for example, substantially the same. Specifically, the diameter R1 in the X direction of the stage pin 42 decreases from the center portion toward the outer peripheral portion of the lower stage 230a, and the diameters R2 in the Y direction of the stage pins 42 are substantially the same. Here, “substantially the same” includes, for example, errors of several micrometers. Although FIG. 11 shows, as an example, a case where a plurality of stage pins 42 are arranged in a lattice pattern, the stage pins 42 may not be arranged strictly in a lattice pattern. The fact that the diameter of the stage pin 42 decreases from the center portion toward the outer peripheral portion of the lower stage 230a can include a case where stage pins 42 having substantially the same diameter are continuously arranged.

FIG. 12 is a cross-sectional view taken along line XII-XII of FIG. 11, showing an example of a cross-sectional structure along the X direction of the lower stage 230a in the second configuration example of the bonding apparatus 2 according to the first embodiment. As shown in FIG. 12, in the second configuration example, the diameter R1e in the X direction of, among the stage pins 42 arranged in the X direction, a stage pin 42 placed in the outer peripheral portion of the lower stage 230a is smaller than the diameter R1c in the X direction of a stage pin 42 placed in the center portion of the lower stage 230a. In the lower stage 230a, the diameters R1 in the X direction of the stage pins 42 are, for example, in the range of 100 to 1000 μm. Specifically, the diameter R1c in the X direction of a stage pin 42 in the center portion is, for example, 1000 μm. The diameter Rle in the X direction of a stage pin 42 in the outer peripheral portion is, for example, 100 μm.

FIG. 13 is a cross-sectional view taken along line XIII-XIII of FIG. 11, showing an example of a cross-sectional structure along the Y direction of the lower stage 230a in the second configuration example of the bonding apparatus 2 according to the first embodiment. In the second configuration example, the diameter R2e in the X direction of, among the stage pins 42 arranged in the Y direction, a stage pin 42 placed in the outer peripheral portion of the lower stage 230a is substantially the same as the diameter R2c in the X direction of a stage pin 42 placed in the center portion of the lower stage 230a. In the lower stage 230a, the diameters R2 in the Y direction of the stage pins 42 are, for example, in the range of 100 to 1000 μm. Specifically, each of the diameter R2c in the Y direction of a stage pin 42 in the center portion of the lower stage 230a and the diameter R2e in the Y direction of a stage pin 42 in the outer peripheral portion is, for example, 500 μm. Therefore, the diameters of the stage pins 42 have relationships of R1c>R2c=R2e>R1e.

The size of the stage pin 42 in the second configuration example may be adjusted by changing the diameter R2 in the Y direction. It is sufficient that the lower stage 230a of the second configuration example be designed such that, in the X direction, the ratio of the area of the places where the lower wafer LW and the stage pins 42 are in contact decreases from the center portion toward the outer peripheral portion of the lower stage 230a. In the lower stage 230a of the second configuration example, the ratio between the diameter R1 in the X direction and the diameter R2 in the Y direction is preferably in the range of 0.3 to 3.0. Further, in the lower stage 230a of the second configuration example, the ratio of the area of the places where the lower wafer LW and the stage pins 42 are in contact is preferably in the range of 1 to 25%. In this case, the ratio of the area of the upper surfaces of the stage pins 42 (that is, the places where the stage pins 42 and the lower wafer LW are in contact) in the center portion of the lower stage 230a is 25%, and the ratio of the area of the upper surfaces of the stage pins 42 in the outer peripheral portion of the lower stage 230a is 18. In other words, in the lower stage 230a of the second configuration example, the contact area between the lower wafer LW and the stage pins 42 in a 1-cm² area at the time of suction of the lower wafer LW is 0.25 cm² (that is, the contact ratio=25%) in the center portion and 0.01 cm² (that is, the contact ratio=18) in the outer peripheral portion.

### Third Configuration Example

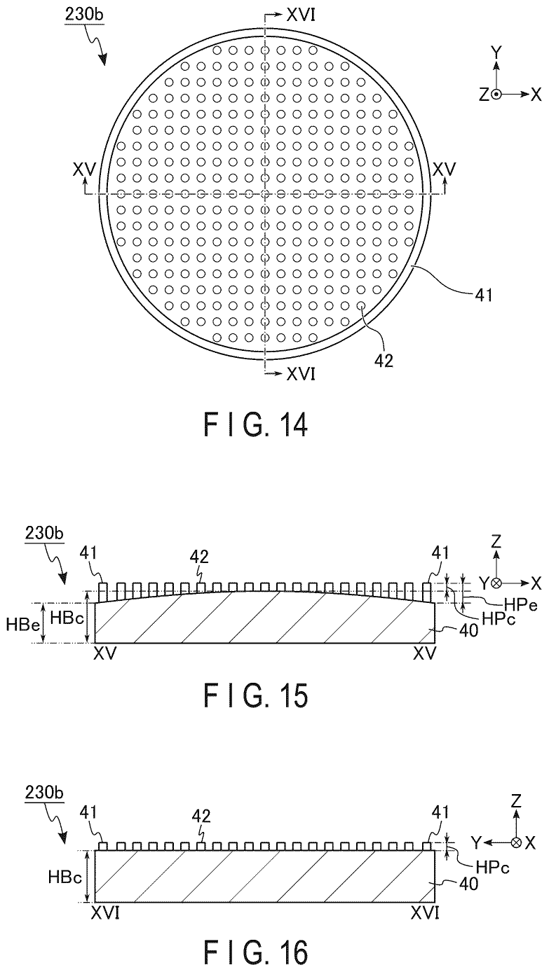

FIG. 14 is a plan view showing an example of a planar layout of a lower stage 230b in a third configuration example of the bonding apparatus 2 according to the first embodiment. As shown in FIG. 14, in the lower stage 230b of the third configuration example, stage pins 42 having the same size are arranged in a lattice pattern. Although FIG. 14 shows, as an example, a case where a plurality of stage pins 42 are arranged in a lattice pattern, the stage pins 42 may not be arranged strictly in a lattice pattern.

FIG. 15 is a cross-sectional view taken along line XV-XV of FIG. 14, showing an example of a cross-sectional structure along the X direction of the lower stage 230b in the third configuration example of the bonding apparatus 2 according to the first embodiment. As shown in FIG. 15, in the lower stage 230b of the third configuration example, a plurality of stage pins 42 are arranged such that the height changes in the X direction. Here, the “height of the stage pin 42” corresponds to the length along the Z direction between the bottom and the upper surface of the stage pin 42.

For example, the height of the stage pin 42 included in the stage pins 42 arranged in the X direction increases from a center portion toward an outer peripheral portion of the lower stage 230b (the body part 40). In this example, the height HPc of, among the stage pins 42 arranged in the X direction, a stage pin 42 in the center portion of the lower stage 230b is lower than the height HPe of a stage pin 42 in the outer peripheral portion of the lower stage 230b. In the lower stage 230b, the heights HP of the stage pins 42 are, for example, in the range of 100 to 2000 μm. Specifically, the height HPc of a stage pin 42 in the center portion is, for example, 100 μm. The height HPe of a stage pin 42 in the outer peripheral portion is, for example, 2000 μm.

The lower stage 230b of the third configuration example may be expressed by the thickness of the body part 40. In this case, in a cross section along the X direction, the thickness of the body part 40 of the lower stage 230b decreases from the center portion toward the outer peripheral portion. That is, the thickness HBc of the center portion of the lower stage 230b is thicker than the thickness HBe of the outer peripheral portion of the lower stage 230b. The fact that the height of the stage pin 42 increases from the center portion toward the outer peripheral portion of the lower stage 230b can include a case where stage pins 42 having substantially the same height are continuously arranged.

FIG. 16 is a cross-sectional view taken along line XVI-XVI of FIG. 14, showing an example of a cross-sectional structure along the Y direction of the lower stage 230b in the third configuration example of the bonding apparatus 2 according to the first embodiment. As shown in FIG. 16, in the lower stage 230b of the third configuration example, the stage pins 42 arranged in the Y direction are provided to have substantially the same height. For example, in a cross section along the Y direction including the center portion of the lower stage 230b, the height of the stage pin 42 is HPc, and the thickness of the body part 40 of the lower stage 230b is HBC.

Although the above description gives, as an example, a case where the height is changed for the stage pins 42 arranged in the X direction, the configuration is not limited thereto. The lower stage 230b of the third configuration example may be configured such that the height of the stage pin 42 included in the stage pins 42 arranged in the Y direction increases from the center portion toward the outer peripheral portion of the lower stage 230b (the body part 40).

### <1-1-4> Configuration of the Server 3

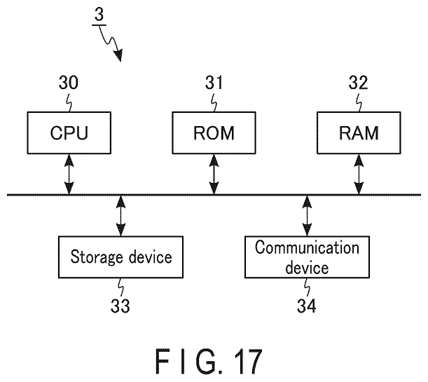

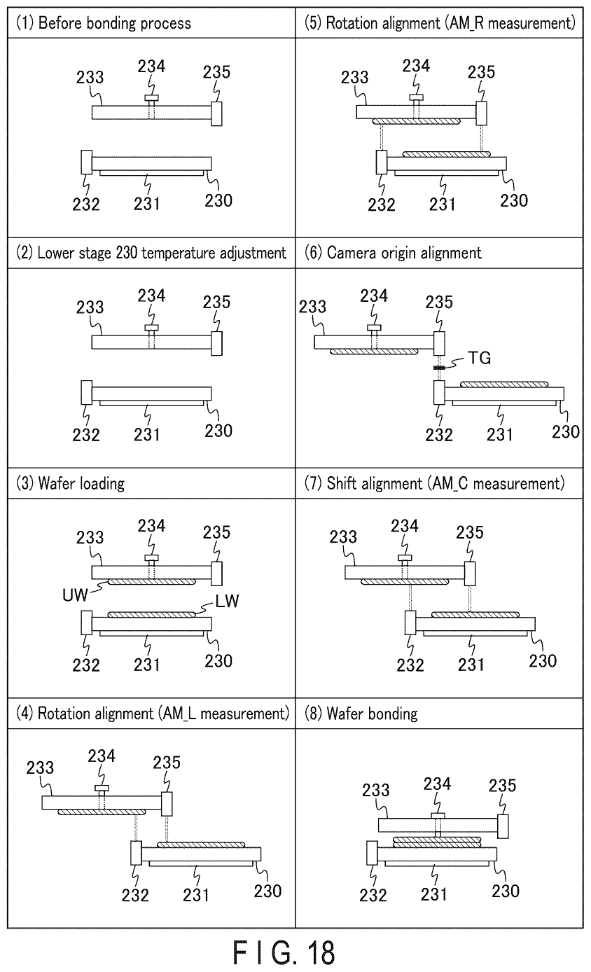

FIG. 17 is a block diagram showing an example of a configuration of the server 3 included in the semiconductor manufacturing system PS according to the first embodiment. As shown in FIG. 17, the server 3 includes, for example, a CPU 30, a ROM 31, a RAM 32, a storage device 33, and a communication device 34. The CPU 30 is a processor that executes various programs relating to control of the server 3. The ROM 31 is a nonvolatile storage device that stores a control program of the server 3. The RAM 32 is a volatile storage device used as a work area of the CPU 30. The storage device 33 is a nonvolatile storage medium capable of storing information received from the exposure apparatus 1, the bonding apparatus 2, etc. The communication device 34 is a communication interface capable of connecting to the network NW.

### <1-2> Manufacturing Method

As a method for manufacturing a semiconductor device according to the first embodiment, a specific example of a process using the exposure apparatus 1, the bonding apparatus 2, and the server 3 will now be described. That is, a semiconductor device can be manufactured using a bonding method (bonding process) of the first embodiment described below.

### <1-2-1> Outline of Bonding Process

FIG. 18 is a schematic diagram showing an outline of bonding process in the bonding apparatus 2 according to the first embodiment. Each of (1) to (8) of FIG. 18 shows a state of the bonding unit 23 in the bonding process. In the following description, the alignment of the shift component is referred to as “shift alignment”, and the alignment of the rotation component is referred to as “rotation alignment”.

(1) of FIG. 18 shows a state of the bonding unit 23 before the bonding process.

Upon starting the bonding process, as shown in (2) of FIG. 18, the control device 20 controls the heater 44 based on a difference between the XY differences of wafer magnification components of the upper wafer UW and the lower wafer LW that are objects to be subjected to the bonding process, and adjusts the temperature of the lower stage 230. The bonding apparatus 2 may acquire information of the XY difference of wafer magnification components from the server 3, or may calculate such information based on alignment correction values acquired from the exposure apparatus 1 or the server 3. After the process of (2) of FIG. 18, the control device 20 may control the stress device 231 based on alignment correction values to wafer magnification components common to the X direction and the Y direction, and deform the lower stage 230.

Next, the control device 20 causes the carrier device 22 to convey the lower wafer LW to the lower stage 230 and convey the upper wafer UW to the upper stage 233. Then, as shown in (3) of FIG. 18, the control device 20 causes the lower stage 230 to hold the lower wafer LW, and causes the upper stage 233 to hold the upper wafer UW. The surfaces of the upper wafer UW and the lower wafer LW to be conveyed to the bonding apparatus 2 have been modified and hydrophilized by the pre-process device for the bonding process.

Next, the control device 20 executes rotation alignment. Specifically, first, as shown in (4) of FIG. 18, the control device 20 controls the positions of the lower stage 230 and the upper stage 233, and thus aligns the optical axis of the camera 232 of the lower stage 230 with the position of alignment mark AM_L of the upper wafer UW and aligns the optical axis of the camera 235 of the upper stage 233 with the position of alignment mark AM_L of the lower wafer LW. Then, the control device 20 uses the camera 232 to measure alignment mark AM_L of the upper wafer UW, and uses the camera 235 to measure alignment mark AM_L of the lower wafer LW.

Next, as shown in (5) of FIG. 18, the control device 20 controls the positions of the lower stage 230 and the upper stage 233, and thus aligns the optical axis of the camera 232 of the lower stage 230 with the position of alignment mark AM_R of the upper wafer UW and aligns the optical axis of the camera 235 of the upper stage 233 with the position of alignment mark AM_R of the lower wafer LW. Then, the control device 20 uses the camera 232 to measure alignment mark AM_R of the upper wafer UW, and uses the camera 235 to measure alignment mark AM_R of the lower wafer LW. Then, based on the results of measurement of alignment marks AM_L and AM_R by the cameras 232 and 235 acquired by the processes of (4) and (5) of FIG. 18, the control device 20 calculates the amounts of correction to overlay deviation of rotation components.

Next, the control device 20 executes origin alignment of the cameras. Specifically, as shown in (6) of FIG. 18, the control device 20 controls the positions of the lower stage 230 and the upper stage 233, and thus inserts a common target TG between the optical axis of the camera 232 of the lower stage 230 and the optical axis of the camera 235 of the upper stage 233. Then, based on the results of measurement of the common target TG by the cameras 232 and 235, the control device 20 aligns the origins of the cameras 232 and 235.

Next, the control device 20 executes shift alignment. Specifically, first, as shown in (7) of FIG. 18, the control device 20 controls the positions of the lower stage 230 and the upper stage 233, and thus aligns the optical axis of the camera 232 of the lower stage 230 with the position of alignment mark AM_C of the upper wafer UW and aligns the optical axis of the camera 235 of the upper stage 233 with the position of alignment mark AM_C of the lower wafer LW. Then, the control device 20 uses the camera 232 to measure alignment mark AM_C of the upper wafer UW, and uses the camera 235 to measure alignment mark AM_C of the lower wafer LW. Then, based on the results of measurement of alignment marks AM_C of the lower wafer LW and the upper wafer UW, the control device 20 calculates alignment correction values to shift components.

Next, as shown in (8) of FIG. 18, the control device 20 executes a bonding sequence. Specifically, first, the control device 20 performs alignment in the horizontal direction based on the alignment correction values calculated by rotation alignment and shift alignment and the result of calibration of the camera origins, and adjusts the relative positions of the lower stage 230 and the upper stage 233. Then, the control device 20 brings the position of the upper stage 233 close to the lower stage 230 to adjust the gap between the upper wafer UW and the lower wafer LW. Then, the control device 20 lowers the pushpin 234 to push down a center portion of the upper wafer UW, and thus brings the surface of the upper wafer UW and the surface of the lower wafer LW into contact with each other.

After that, the control device 20 sequentially releases the holding (vacuum suction) of the upper wafer UW by the upper stage 233 from the inside toward the outside. Then, the upper wafer UW drops onto the lower wafer LW, and the surface of the upper wafer UW and the surface of the lower wafer LW are bonded. Specifically, van der Waals force (intermolecular force) is generated between the modified bonding surface of the upper wafer UW and the modified bonding surface of the lower wafer LW, and the contact portions of the upper wafer UW and the lower wafer LW are bonded. Further, since the bonding surfaces of the upper wafer UW and the lower wafer LW have been hydrophilized, hydrophilic groups of the contact portions of the upper wafer UW and the lower wafer LW produce hydrogen bonding (intermolecular force), and the contact portions of the upper wafer UW and the lower wafer LW are bonded more firmly.

### (Temperature Change of the Lower Wafer LW)

A temperature change of the lower wafer LW held by the lower stage 230 will now be described.

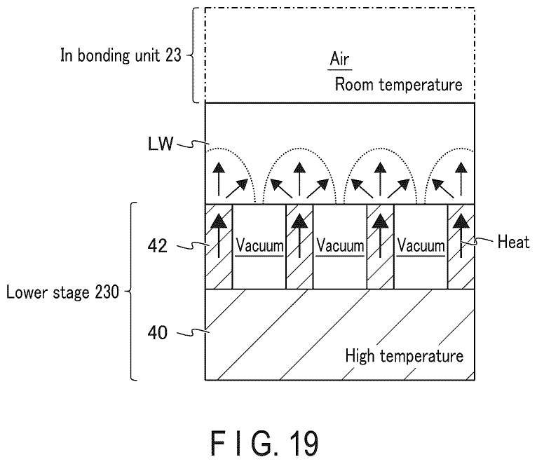

FIG. 19 is a schematic diagram showing how heat is transferred to the lower wafer LW held by the lower stage 230 included in the bonding apparatus 2 according to the first embodiment. As shown in FIG. 19, the temperature of air in the bonding unit 23 corresponds to room temperature (RT). The initial temperature of the lower wafer LW is, for example, room temperature. In a case where the lower wafer LW is held by the lower stage 230, the space surrounded by the bottom surface of the lower wafer LW, the stage pins 42, and the body part 40 becomes a vacuum. In a case where the body part 40 is heated by the heater 44, the heat of the body part 40 is transferred to the bottom of the lower wafer LW via the stage pins 42. On the other hand, the heat of the body part 40 is not transmitted to portions of the lower wafer LW not held by the stage pins 42 due to the vacuum condition.

In the lower stage 230 of the first configuration example and the lower stage 230a of the second configuration example, the conductivity of heat from the lower stage 230 to the lower wafer LW can be changed in the wafer plane according to the ratio of the area of the contact places between the lower wafer LW and the stage pins 42. In the lower stage 230b of the third configuration example, the conductivity of heat from the lower stage 230b to the lower wafer LW can be changed in the wafer plane according to the length of the stage pin 42 to pass through. The obtained effects are similar in all of the first to third configuration examples of the lower stage 230. In the following, a case where the lower stage 230 of the first configuration example like that shown in FIG. 8 is used is mainly described.

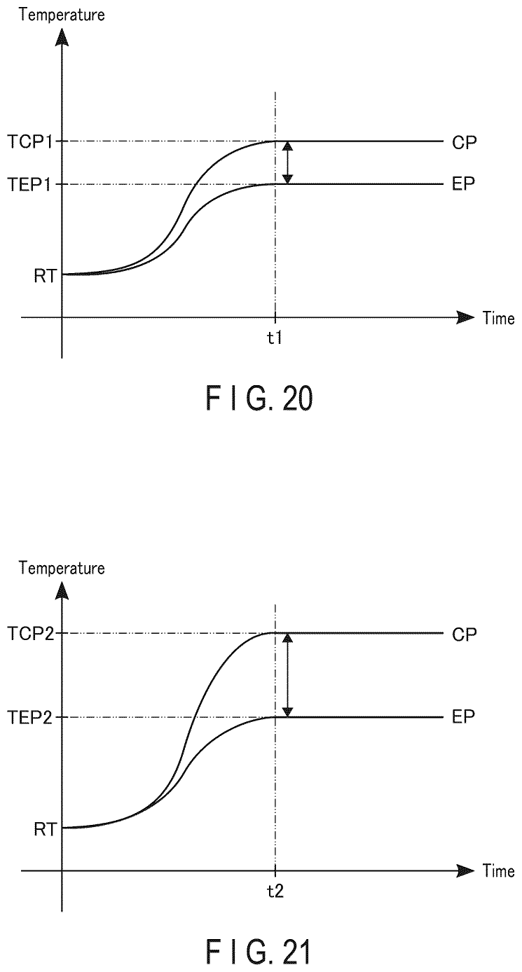

FIGS. 20 and 21 are graphs showing a first example and a second example, respectively, which are two examples of temperature change of the lower wafer LW held by the lower stage 230 included in the bonding apparatus 2 according to the first embodiment. The horizontal axis of the graphs shown in FIGS. 20 and 21 represents time, and the vertical axis represents the temperature in each of a center portion CP and an outer peripheral portion EP of the lower wafer LW. The temperature of the lower stage 230 is different between the first example and the second example. Specifically, the lower stage 230 of the second example is adjusted to a higher temperature than the lower stage 230 of the first example. In a case where the lower wafer LW is held by the lower stage 230, heat is transferred from the body part 40 of the lower stage 230 to the lower wafer LW via the stage pins 42, and the temperature of the lower wafer LW rises from room temperature RT.

As shown in FIG. 20, in the first example, at time t1, the temperature of the center portion CP of the lower wafer LW rises to TCP1, and the temperature of the outer peripheral portion EP of the lower wafer LW rises to TEP1. After that, the temperatures of the center portion CP and the outer peripheral portion EP of the lower wafer LW enter an equilibrium state based on heat transferred via the stage pins 42 and the room temperature of the bonding unit 23. At this time, since the thermal conductivity of the center portion CP is higher than the thermal conductivity of the outer peripheral portion EP, temperature TCP1 is higher than temperature TEP1.

On the other hand, as shown in FIG. 21, in the second example, at time t2, the temperature of the center portion CP of the lower wafer LW rises to TCP2, and the temperature of the outer peripheral portion EP of the lower wafer LW rises to TEP2. After that, the temperatures of the center portion CP and the outer peripheral portion EP of the lower wafer LW enter an equilibrium state based on heat transferred via the stage pins 42 and the room temperature of the bonding unit 23. At this time, since the thermal conductivity of the center portion CP is higher than the thermal conductivity of the outer peripheral portion EP, temperature TCP2 is higher than temperature TEP2.

The bonding of the lower wafer LW and the upper wafer UW is preferably executed after the temperature of the lower wafer LW reaches an equilibrium state. The temperature difference between the center portion CP and the outer peripheral portion EP after reaching an equilibrium state is larger in the second example than in the first example based on the fact that the temperature of the lower stage 230 is higher in the second example than in the first example. Thus, the bonding apparatus 2 according to the first embodiment can adjust the temperature difference in the wafer plane in the X direction of the lower wafer LW by temperature adjustment of the lower stage 230. As a result, the XY difference of wafer magnification components of the lower wafer LW can be adjusted based on the temperature difference in the wafer plane and the coefficient of thermal expansion of the lower wafer LW. On the other hand, by temperature adjustment of the lower stage 230, heating is performed in the Y direction of the lower wafer LW, and the temperature difference in the wafer plane is suppressed. Thus, a change of the wafer magnification component in the Y direction is suppressed. Therefore, the bonding apparatus 2 can adjust the XY difference of wafer magnification components by temperature adjustment of the lower stage 230. The timing at which the temperature of the lower wafer LW reaches an equilibrium state by temperature adjustment of the lower stage 230 can be different between the center portion CP and the outer peripheral portion EP. For example, in a case where the lower wafer LW is mounted on the lower stage 230 of any of the first to third configuration examples and heat is transferred to the lower wafer LW via the stage pins 42, along the Y direction, the temperature of the center portion CP in the X direction of the lower wafer LW becomes relatively high and the temperature of the outer peripheral portion EP in the X direction of the lower wafer LW becomes relatively low. For example, since a semiconductor substrate (wafer) expands in a case where temperature rises, the lower wafer LW mounted on the lower stage 230 of any of the first to third configuration examples expands more in the Y direction than in the X direction. In a case where it is desired to expand the lower wafer LW more in the X direction than in the Y direction, for example, the lower wafer LW may be mounted on the lower stage 230 in a state where the lower wafer LW is rotated by 90 degrees.

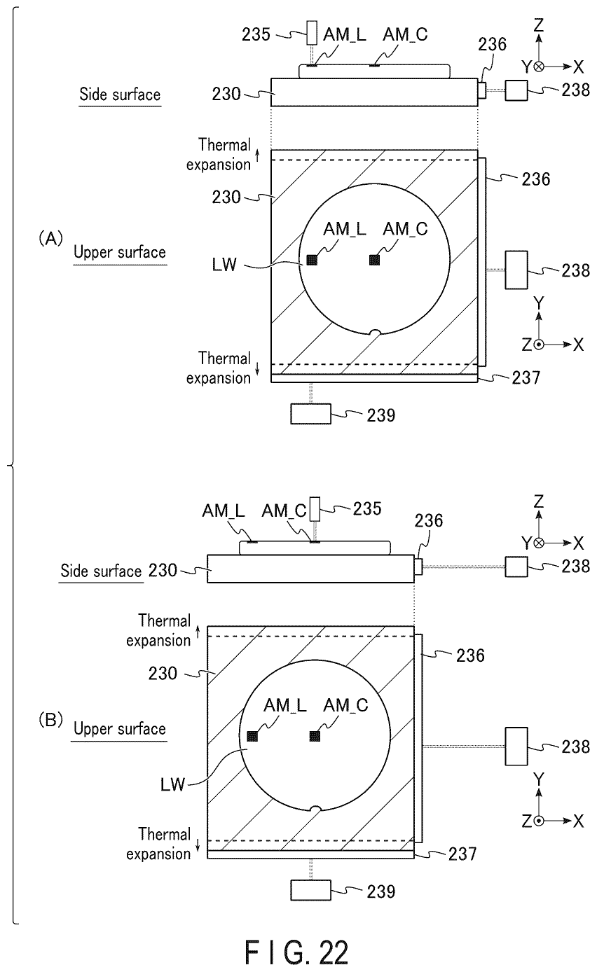

(Influence of Thermal Expansion of the Lower Stage 230) FIG. 22 is a diagram describing influence of thermal expansion of the lower stage 230 in the bonding apparatus 2 according to the first embodiment. (A) and (B) of FIG. 22 show the positions of the lower stage 230 in cases where alignment mark AM_L located in the outer peripheral portion and alignment mark AM_C located in the center portion are measured, respectively, and show the side surface and the upper surface of lower stage 230. Further, (A) and (B) of FIG. 22 show part of the configuration used for position control of the lower stage 230 as well.

The bonding unit 23 further includes, for example, movable mirrors 236 and 237 and interferometers 238 and 239. The movable mirrors 236 and 237 are installed on the lower stage 230 such that they can reflect light applied from the X direction and the Y direction, respectively. Each of the interferometers 238 and 239 calculates the movement distance of the stage from the difference between light waves of a fixed beam and a moving beam. Specifically, the interferometer 238 calculates the movement distance in the X direction of the lower stage 230 by using reflected light from the movable mirror 236. The interferometer 239 calculates the movement distance in the Y direction of the lower stage 230 by using reflected light from the movable mirror 237. Thus, the control device 20 can control the position of the lower stage 230 based on measurement results of the interferometers 238 and 239.

In a case where the lower stage 230 is heated by the heater 44 (see FIG. 7), the lower stage 230 is thermally expanded. In FIG. 22, a state where the lower stage 230 is thermally expanded is shown only for the Y direction. Although thermal expansion of the lower stage 230 occurs in both the X direction and the Y direction, FIG. 22 shows only thermal expansion in the Y direction. Since the heater 44 is configured to control the temperature of the entire lower stage 230 substantially uniformly, the amount of thermal expansion in the Y direction of the lower stage 230 accompanying the temperature change of the lower stage 230 can be substantially uniform between the center portion and the end side in the X direction of the lower stage 230. Thus, in the bonding apparatus according to the first embodiment, in a case where the interferometer 239 is taken as a reference in alignment measurement of the lower wafer LW, a difference in result of measurement of the wafer position in the Y direction can be suppressed between a case where alignment mark AM_C in the center portion is measured and a case where alignment mark AM_L on the end side is measured.

### <1-2-2> Learning Method

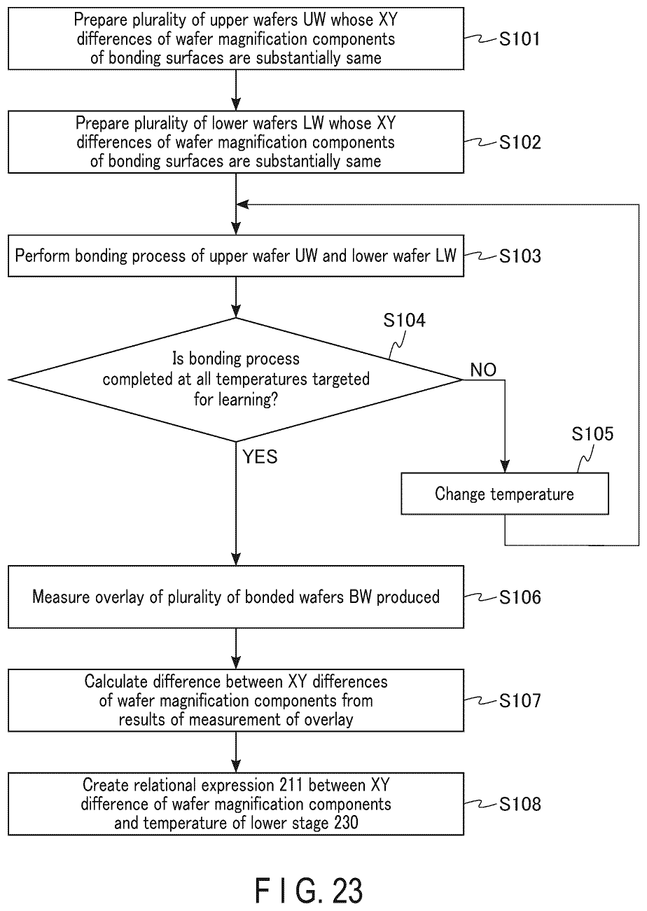

FIG. 23 is a flowchart showing an example of a method of learning wafer magnification correction values in the semiconductor manufacturing system PS according to the first embodiment. The wafer magnification correction value is a correction value to a wafer magnification component described later. As a method of learning wafer magnification correction values, an example of a sequence that generates a relational expression 211 will now be described with reference to FIG. 23.

First, a plurality of upper wafers UW of which the XY differences of wafer magnification components of the bonding surfaces are substantially the same are prepared (step S101), and a plurality of lower wafers LW of which the XY differences of wafer magnification components of the bonding surfaces are substantially the same are prepared (step S102). In the present specification, the “wafer magnification component of the bonding surface” is based on, for example, an alignment result measured by the exposure apparatus 1 in a lithography step performed last in a front-end process. For the “wafer magnification component of the bonding surface”, a numerical value of a wafer magnification component measured in another step may be used as long as it can be used to adjust overlay of the upper wafer UW and the lower wafer LW in the bonding process. The upper wafers UW and the lower wafers LW prepared are conveyed to the bonding apparatus 2 according to the first embodiment. The bonding apparatus 2 includes the lower stage 230 in any of the first to third configuration examples.

Next, the bonding process of the lower wafer LW and upper wafer UW prepared is executed (step S103). In the process of step S103, the temperature of the lower stage 230 is adjusted to a predetermined temperature among temperatures targeted for learning, and at least one set of the lower wafer LW and the upper wafer UW is bonded. The predetermined temperature may be, for example, a temperature of the heater 44. In a case where the bonding process of at least one set of the lower wafer LW and the upper wafer UW using the predetermined temperature is completed, the bonding apparatus 2 checks whether the bonding process is completed at all the temperatures targeted for learning or not (step S104).

In a case where the bonding process is not completed at all the temperatures targeted for learning (step S104: NO), the bonding apparatus 2 changes the temperature (step S105), and proceeds to the process of step S103. That is, the bonding apparatus 2 executes the bonding process of at least one set of the lower wafer LW and the upper wafer UW by using a temperature different from the previous temperature. In a case where the bonding process is completed at all the temperatures targeted for learning (step S104: YES), the semiconductor manufacturing system PS proceeds to the process of step S106.

In the process of step S106, an overlay inspection device is used to measure the overlay of the bonded wafers BW produced by the process of step S103. The results of measurement of overlay are transferred to, for example, the server 3. Then, from the results of measurement of overly of the bonded wafers BW, the server 3 calculates a difference between the XY differences of wafer magnification components of the lower wafer LW and the upper wafer UW (referred to as an XY difference of wafer magnification components of the bonded wafer BW) at each of the temperatures used (step S107). Then, the server 3 creates a relational expression 211 between the XY difference of wafer magnification components of the bonded wafer BW and the temperature of the lower stage 230 (step S108). The temperature of the lower stage 230 in step S108 may be the temperature of the heater 44. After that, the server 3 transfers the created relational expression 211 to the bonding apparatus 2, and the bonding apparatus 2 saves the relational expression 211 transferred from the server 3 in the storage device 21. The processes of steps S107 and S108 may be executed by the bonding apparatus 2.

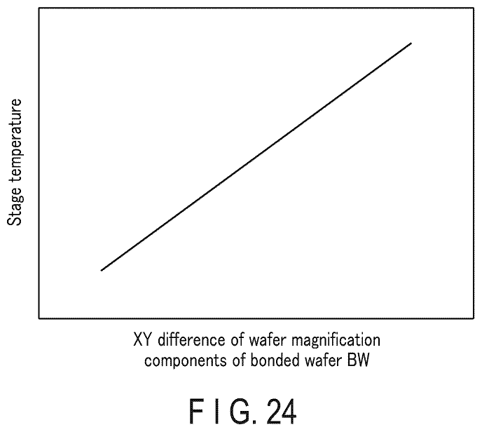

FIG. 24 is a graph showing an example of a result of learning of wafer magnification correction values in the semiconductor manufacturing system PS according to the first embodiment. The horizontal axis of the graph shown in FIG. 24 represents the XY difference of wafer magnification components of the bonded wafer BW, and the vertical axis represents the temperature of the lower stage 230. As shown in FIG. 24, the XY difference of wafer magnification components of the bonded wafer BW and the temperature of the lower stage 230 can be expressed by, for example, a relational expression 211 of a linear function. That is, the XY difference of wafer magnification components of the bonded wafer BW in the bonding process increases as the temperature of the lower stage 230 increases. By using such a relational expression 211, which is a result of learning of wafer magnification correction values, the bonding apparatus 2 can, based on information of the wafer magnification of each of the lower wafer LW and the upper wafer UW to be bonded, select a temperature of the lower stage 230 at which the XY difference of wafer magnification components of the bonded wafer BW in bonding overlay measurement is close to zero.

### <1-2-3> Bonding Method

As a bonding method using the bonding apparatus 2 according to the first embodiment, an example of a the bonding process sequence using the relational expression 211 will now be described.

### First Example

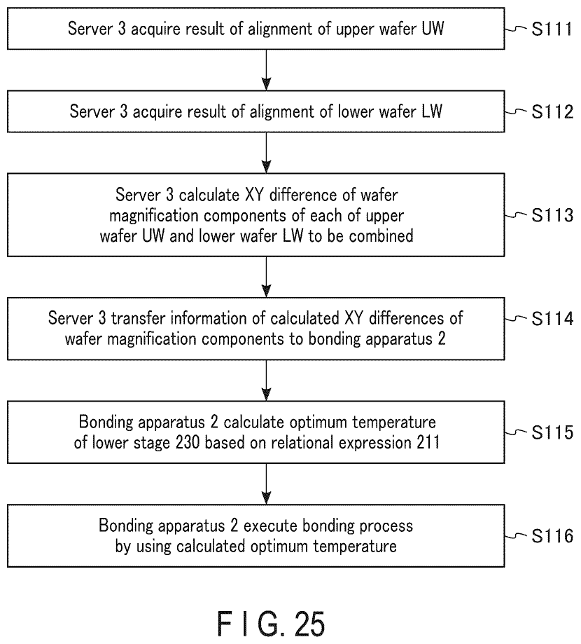

FIG. 25 is a flowchart showing a first example of a bonding method of the bonding apparatus 2 according to the first embodiment. An example of a sequence in a case where the bonding apparatus 2 executes the bonding process by using a result of calculation of an XY difference of wafer magnification components of the bonded wafer BW by the server 3 will now be described with reference to FIG. 25.

First, the server 3 acquires a result of alignment of the upper wafer UW (step S111). The result of alignment of the upper wafer UW corresponds to a result of alignment measurement in the exposure process serving as a reference of overlay adjustment during the bonding process. Instead of a result of alignment of the upper wafer UW, a result of overlay inspection by an overlay inspection device may be used.

Next, the server 3 acquires a result of alignment of the lower wafer LW (step S112). The result of alignment of the lower wafer LW corresponds to a result of alignment measurement in the exposure process serving as a reference of overlay adjustment during the bonding process. Instead of a result of alignment of the lower wafer LW, a result of overlay inspection by an overlay inspection device may be used.

Next, the server 3 calculates an XY difference of wafer magnification components of each of the upper wafer UW and the lower wafer LW to be combined (step S113). Then, the server 3 transfers information of the calculated XY differences of wafer magnification components to the bonding apparatus 2 (step S114). The bonding apparatus 2 saves the information of the XY differences of wafer magnification components transferred from the server 3 in, for example, the storage device 21. Next, the bonding apparatus 2 calculates (or selects) an optimum temperature of the lower stage 230 based on the relational expression 211 (step S115). The calculation of an optimum temperature of the lower stage 230 is, for example, executed for each combination of the upper wafer UW and the lower wafer LW. Then, using the calculated optimum temperature, the bonding apparatus 2 executes the bonding process on the associated combination of the lower wafer LW and the upper wafer UW (step S116).

### Second Example

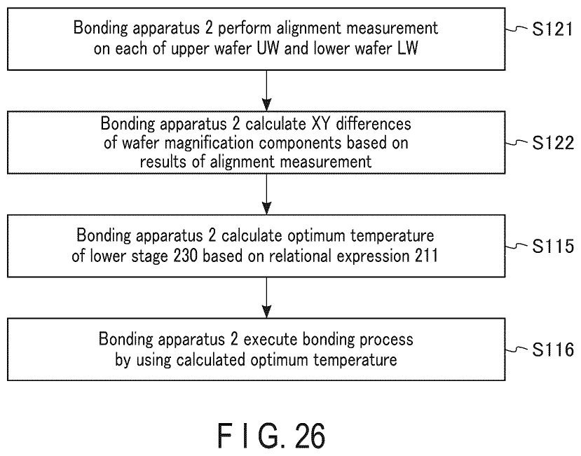

FIG. 26 is a flowchart showing a second example of a bonding method of the bonding apparatus according to the first embodiment. An example of a sequence in a case where the bonding apparatus 2 calculates XY differences of wafer magnification components by itself and executes the bonding process will now be described with reference to FIG. 26.

First, the bonding apparatus 2 executes alignment measurement of each of the upper wafer UW and the lower wafer LW (step S121). That is, in the second example, processes corresponding to (4) to (7) of FIG. 18 is executed before the process of (2) of FIG. 18. Then, based on the results of alignment measurement, the bonding apparatus 2 calculates XY differences of wafer magnification components of the upper wafer UW and the lower wafer LW to be combined (step S122). Then, like in the first example of the bonding method, the bonding apparatus 2 calculates an optimum temperature of the lower stage 230 based on the relational expression 211 (step S115), and executes the bonding process on the associated combination of the lower wafer LW and the upper wafer UW by using the calculated optimum temperature (step S116).

### <1-3> Advantageous Effects of the First Embodiment

By the semiconductor manufacturing system PS according to the first embodiment, the yield of semiconductor devices can be improved. Details of advantageous effects of the first embodiment will now be described.

In a semiconductor device having a bonding structure, a difference between the XY differences of wafer magnification components of the upper wafer UW and the lower wafer LW may cause deterioration of bonding overlay of the bonded wafer BW. In the bonding apparatus 2, wafer magnification components common to the X direction and the Y direction of the upper wafer UW and the lower wafer LW can be corrected by, for example, deforming the lower stage 230 with the stress device 231. On the other hand, the stress device 231 cannot correct an XY difference of wafer magnification components.

In contrast, in the lower stage 230 in the bonding apparatus 2 according to the first embodiment, the arrangement density, shape, or height of a plurality of stage pins 42 of the lower stage 230 is configured such that the conductivity of heat varies between the X direction and the Y direction in the wafer plane. In other words, a plurality of stage pins 42 arranged in one direction (for example, the X direction) are configured such that at least one of the area and the length is different between the center portion and the outer peripheral portion of the lower stage 230.

Thereby, the bonding apparatus 2 according to the first embodiment can, in the lower wafer LW, generate a desired temperature difference in the wafer plane. Then, the bonding apparatus 2 according to the first embodiment can generate a temperature difference (thermal expansion difference) between the X direction and the Y direction of the lower wafer LW, and can adjust the XY difference of wafer magnification components between the lower wafer LW and the upper wafer UW. As a result, the bonding apparatus 2 according to the first embodiment can equalize the XY differences of wafer magnification components of the lower wafer LW and the upper wafer UW, and can suppress overlay deviation in bonding overlay of the bonded wafer BW. Therefore, the semiconductor manufacturing system PS according to the first embodiment can improve the accuracy of bonding overlay, and can improve the yield of semiconductor devices having a bonding structure.

### <2> Second Embodiment

In a semiconductor manufacturing system PS according to a second embodiment, the bonding apparatus 2 is configured to create a relational expression 211 by using one bonded wafer BW. The semiconductor manufacturing system PS according to the second embodiment will now be described centering on differences from the first embodiment.

### <2-1> Configuration

The configuration of the semiconductor manufacturing system PS according to the second embodiment is similar to that of the first embodiment.

### <2-2> Manufacturing Method

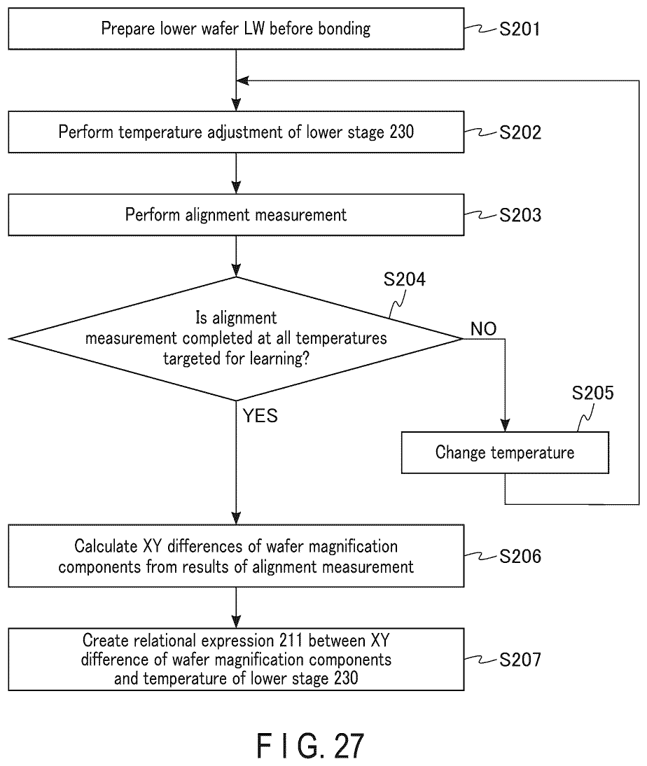

FIG. 27 is a flowchart showing an example of a method of learning wafer magnification correction values in the semiconductor manufacturing system PS according to the second embodiment. As a method of learning wafer magnification correction values, an example of a sequence that generates a relational expression 211 will now be described with reference to FIG. 27.

First, a lower wafer LW before bonding is prepared (step S201). In the present specification, the “lower wafer LW before bonding” corresponds to a lower wafer LW for which a front-end process is completed. The prepared lower wafer LW is conveyed to the bonding apparatus 2, and is held by the lower stage 230.

Next, temperature adjustment of the lower stage 230 is executed (step S202). As the temperature of the lower stage 230, a predetermined temperature targeted for learning is used. Then, after the temperature of the lower stage 230 for which temperature adjustment has been executed and the temperature of the lower wafer LW enter an equilibrium state, the bonding apparatus 2 uses the camera 235 on the upper stage 233 side to execute alignment measurement (step S203). As an object to be subjected to alignment measurement in step S203, a bonding layer formed in the front-end process or a layer in the vicinity of the bonding layer is used. The result of alignment measurement is saved in, for example, the storage device 21. In a case where the alignment measurement is completed, the bonding apparatus 2 checks whether alignment measurement is completed at all temperatures targeted for learning or not (step S204).

In a case where alignment measurement is not completed at all the temperatures targeted for learning (step S204: NO), the bonding apparatus 2 changes the temperature (step S205), and proceeds to the process of step S202. That is, the bonding apparatus 2 executes temperature adjustment of the lower stage 230 and alignment measurement of the lower wafer LW by using a temperature different from the previous temperature. In a case where alignment measurement is completed at all the temperatures targeted for learning (step S204: YES), the bonding apparatus 2 proceeds to the process of step S206.

In the process of step S206, from the results of alignment measurement, the bonding apparatus 2 calculates an XY difference of wafer magnification components of the lower wafer LW at each of the temperatures used. Then, the bonding apparatus 2 creates a relational expression 211 between the XY difference of wafer magnification components of the lower wafer LW and the temperature of the lower stage 230 (step S207). The temperature of the lower stage 230 in step S207 may be the temperature of the heater 44. After that, the bonding apparatus 2 saves the created relational expression 211 in the storage device 21.

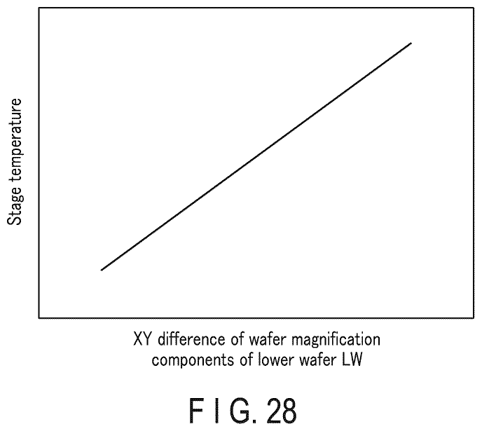

FIG. 28 is a graph showing an example of a result of learning of wafer magnification correction values in the semiconductor manufacturing system PS according to the second embodiment. The horizontal axis of the graph shown in FIG. 28 represents the XY difference of wafer magnification components of the lower wafer LW before bonding, and the vertical axis represents the temperature of the lower stage 230. As shown in FIG. 28, the XY difference of wafer magnification components of the lower wafer LW and the temperature of the lower stage 230 can be expressed by, for example, a relational expression 211 of a linear function. In this case, the amount of correction to the XY difference of wafer magnification components in the bonding process increases as the temperature of the lower stage 230 increases. By using the relational expression 211, which is a result of learning of wafer magnification correction values, the bonding apparatus 2 can, based on information of the XY difference of wafer magnification components of each of the lower wafer LW and the upper wafer UW to be bonded that was acquired in another process, select a temperature of the lower stage 230 at which the XY difference of wafer magnification components of the lower wafer LW is such a value that the difference between the XY differences of wafer magnification components of the lower wafer LW and the upper wafer UW in bonding overlay measurement is close to zero.

### <2-3> Advantageous Effects of the Second Embodiment

The semiconductor manufacturing system PS according to the second embodiment can create a correction formula 211 used to correct the XY difference of wafer magnification components with less resources than in the first embodiment. Therefore, the semiconductor manufacturing system PS according to the second embodiment can obtain similar effects to those of the first embodiment, and can furthermore make the cost required to create a correction formula 211 smaller than in the first embodiment.

### <3> Third Embodiment

A third embodiment relates to a specific example of a semiconductor device manufactured using the bonding method described in the above embodiments. As a specific example of the semiconductor device, a memory device having a bonding structure will now be described.

### <3-1> Overall Configuration of a Memory Device 500

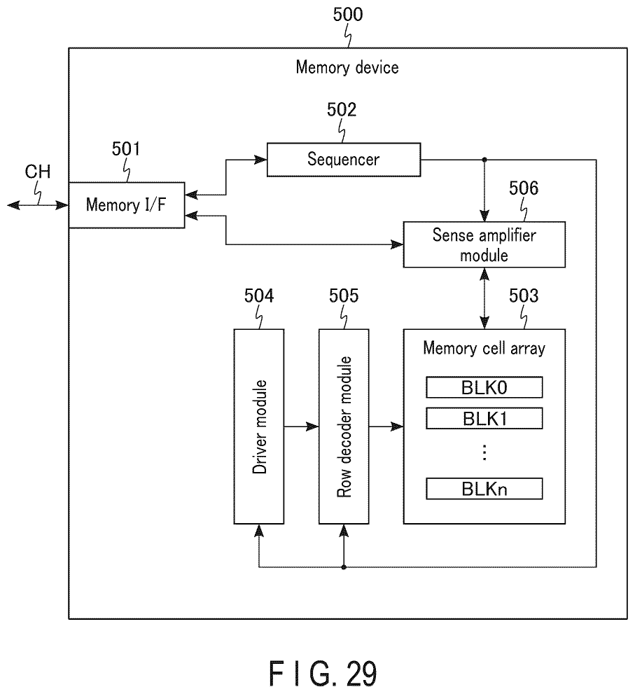

FIG. 29 is a block diagram showing an example of an overall configuration of a memory device 500 according to the third embodiment. As shown in FIG. 29, the memory device 500 includes a memory interface (memory I/F) 501, a sequencer 502, a memory cell array 503, a driver module 504, a row decoder module 505, and a sense amplifier module 506.

The memory I/F 501 is connected to an external memory controller via a channel CH, and performs communication according to an interface standard. The memory I/F 501 supports, for example, a NAND interface standard.

The sequencer 502 is a control circuit that controls the entire operation of the memory device 500. The sequencer 502 controls the driver module 504, the row decoder module 505, the sense amplifier module 506, etc. based on a command received via the memory I/F 501, and executes a read operation, a write operation, an erase operation, etc.

The memory cell array 503 is a storage circuit including a set of memory cells. The memory cell array 503 includes a plurality of blocks BLK0 to BLKn (n is an integer of 1 or more). The memory cell array 503 is provided with a plurality of bit lines and a plurality of word lines. Each of the memory cells is associated with, for example, one of the bit lines BL and one of the word lines WL.

The driver module 504 is a driver circuit that generates voltage used in a read operation, a write operation, an erase operation, etc. The driver module 504 applies the generated voltage to a plurality of signal lines connected to the row decoder module 505.

The row decoder module 505 decodes a row address received via the memory I/F 501, and selects one block BLK based on the decoding result. Then, the row decoder module 505 transfers the voltages applied to the signal lines individually to a plurality of interconnects (word lines WL, etc.) provided in the selected block BLK.

In a read operation, the sense amplifier module 506 determines data read from a selected memory cell based on the voltage of the bit line BL, and transmits the result to the memory controller via the memory I/F 501. In a write operation, the sense amplifier module 506 applies, to each bit line BL, a voltage according to data to be written on a memory cell.

### <3-2> Circuit Configuration of the Memory Cell Array 503

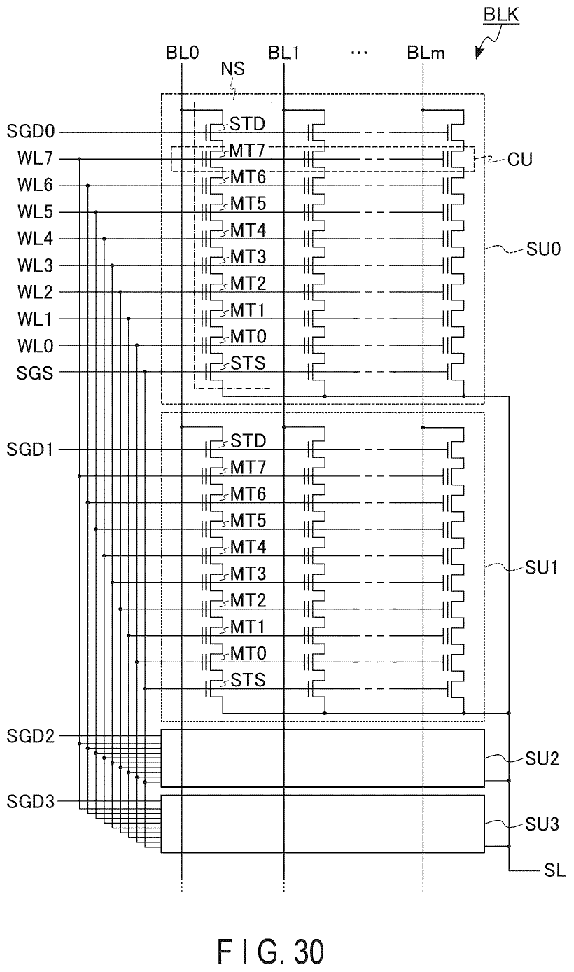

FIG. 30 is a circuit diagram showing an example of a circuit configuration of the memory cell array 503 included in the memory device 500 according to the third embodiment. FIG. 30 shows one block BLK among a plurality of blocks BLK included in the memory cell array 503. As shown in FIG. 30, the block BLK includes, for example, four string units SU0 to SU3.

Each string unit SU includes a plurality of NAND strings NS associated individually with bit lines BLO to BLm (m is an integer of 1 or more). Each bit line BL is shared by the NAND strings NS to which the same column address is allocated among the blocks BLK. Each NAND string NS includes, for example, memory cell transistors MT0 to MT7 and select transistors STD and STS.

Each memory cell transistor MT includes a control gate and a charge storage layer, and stores data in a nonvolatile manner. The memory cell transistors MT0 to MT7 of each NAND string NS are connected in series. The control gates of the memory cell transistors MT0 to MT7 are connected to the word lines WL0 to WL7, respectively. Each of the word lines WL0 to WL7 is provided for each block BLK. A set of memory cell transistors MT connected to a common word line WL in the same string unit SU is referred to as, for example, a “cell unit CU”. The cell unit CU may have a storage capacity of two page data or more according to the number of bits of data stored by the memory cell transistor MT.

Each of the select transistors STD and STS is used to select the string unit SU. The drain of the select transistor STD is connected to the associated bit line BL. The memory cell transistors MT0 to MT7 connected in series are connected between the source of the select transistor STD and the drain of the select transistor STS. Gates of the select transistors STD included in the string units SU0 to SU3 are connected to select gate lines SGD0 to SGD3, respectively. The source of the select transistor STS is connected to the source line SL. The gate of the select transistor STS is connected to the select gate line SGS. The source line SL is shared by a plurality of blocks BLK, for example.

In the memory cell array 503, the numbers of word lines WL, select gate lines SGD, and select gate lines SGS and the numbers of memory cell transistors MT and select transistors STD and STS may be other numbers.

### <3-3> Structure of the Memory Device 500

An example of a structure of the memory device 500 according to the third embodiment will now be described. In the third embodiment, the X direction corresponds to, for example, the extending direction of the word line WL. The Y direction corresponds to, for example, the extending direction of the bit line BL. The Z direction corresponds to the vertical direction with respect to the front surface of a semiconductor substrate (wafer) used to form the memory device 500.

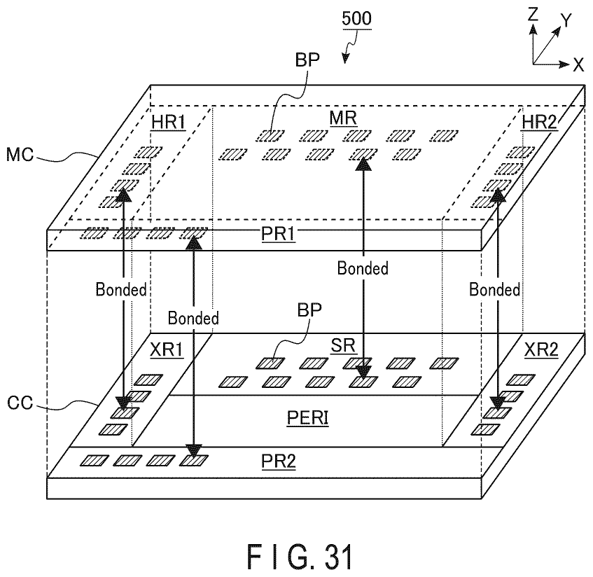

FIG. 31 is a perspective view showing an example of a structure of the memory device 500 according to the third embodiment. As shown in FIG. 31, the memory device 500 includes a memory chip MC and a CMOS chip CC. The memory chip MC includes a memory region MR, hookup regions HR1 and HR2, and a pad region PR1. The CMOS chip CC includes a sense amplifier region SR, a peripheral circuit region PERI, transfer regions XR1 and XR2, and a pad region PR2.

The memory region MR includes the memory cell array 503. Each of the hookup regions HR1 and HR2 includes interconnects used for connection between stacked interconnects provided in the memory chip MC and the row decoder module 505 provided in the CMOS chip CC, etc. The pad region PR1 includes pads used for connection between the memory device 500 and the memory controller, etc. The hookup regions HR1 and HR2 sandwich the memory region MR in the X direction. The pad region PR1 is adjacent, in the Y direction, to the memory region MR and each of the hookup regions HR1 and HR2.

The sense amplifier region SR includes the sense amplifier module 506. The peripheral circuit region PERI includes the sequencer 502, the driver module 504, etc. Each of the transfer regions XR1 and XR2 includes the row decoder module 505. The pad region PR2 includes the memory I/F 501. The sense amplifier region SR and the peripheral circuit region PERI are arranged adjacent in the Y direction, and overlap with the memory region MR in the Z direction. The transfer regions XR1 and XR2 sandwich a set of the sense amplifier region SR and the peripheral circuit region PERI in the X direction, and overlap the hookup regions HR1 and HR2, respectively. The pad region PR2 overlaps with the pad region PR1 of the memory chip MC in the Z direction.

The memory chip MC includes a plurality of bonding pads BP in respective lower parts of the memory region MR, the hookup regions HR1 and HR2, and the pad region PR1, respectively. The bonding pads BP of the memory region MR are connected to the associated bit lines BL. The bonding pads BP of the hookup regions HR are connected to associated interconnect (for example, word lines WL) among the stacked interconnect provided to the memory region MR. The bonding pad BP of the pad region PR1 is connected to a pad (not illustrated) provided to the upper surface of the memory chip MC. The pads provided on the upper surface of the memory chip MC are used for, for example, connection between the memory device 500 and the memory controller.

The CMOS chip CC includes a plurality of bonding pads BP in respective upper parts of the sense amplifier region SR, the peripheral circuit region PERI, the transfer regions XR1 and XR2, and the pad region PR2. The bonding pads BP of the sense amplifier region SR overlap with the bonding pads BP of the memory region MR in the Z direction. The bonding pads BP of the transfer regions XR1 and XR2 overlap with the bonding pads BP of the hookup regions HR1 and HR2 in the Z direction, respectively. The bonding pads BP of the pad region PR1 overlap with the bonding pads BP of the pad region PR2 in the Z direction.

The memory device 500 has a structure in which the lower surface of the memory chip MC (the front surface of a semiconductor substrate on which the memory chip MC is formed) and the upper surface of the CMOS chip CC (the front surface of a semiconductor substrate on which the CMOS chip CC is formed) are bonded. Among the bonding pads BP provided in the memory device 500, two bonding pads BP facing each other between the memory chip MC and the CMOS chip CC are electrically connected by being bonded. Thus, the circuit in the memory chip MC and the circuit in the CMOS chip CC are electrically connected via the bonding pads BP. A set of two bonding pads BP facing each other between the memory chip MC and the CMOS chip CC may have a boundary or may be integrated with one another.

### <3-3-1> Structure of the Memory Cell Array 503

A structure of the memory cell array 503 will now be described.

### (Planar Layout of the Memory Cell Array 503)

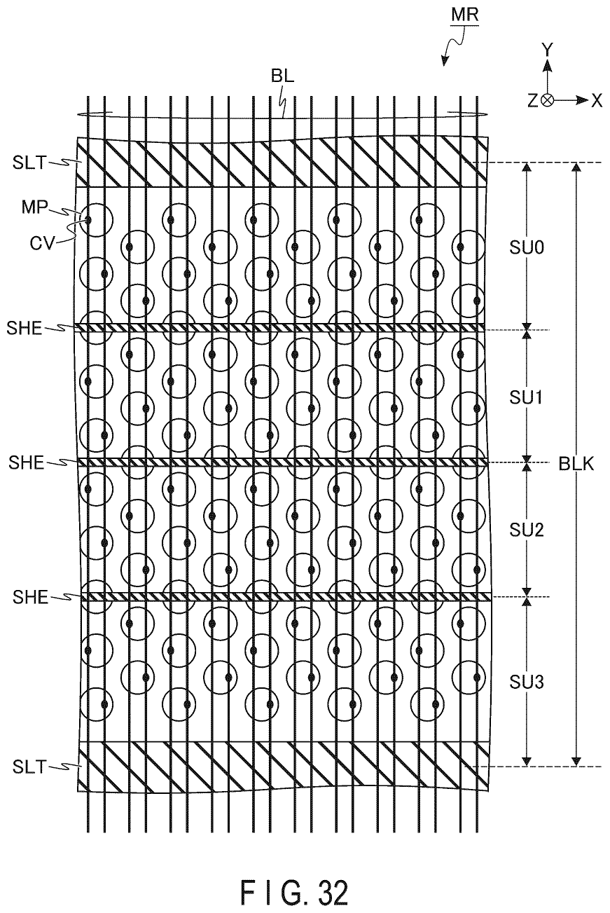

FIG. 32 is a plan view showing an example of a planar layout of the memory cell array 503 included in the memory device 500 according to the third embodiment. FIG. 32 shows an area including one block BLK in the memory region MR. As shown in FIG. 32, the memory device 500 includes a plurality of slits SLT, a plurality of slits SHE, a plurality of memory pillars MP, a plurality of bit lines BL, and a plurality of contacts CV. In the memory region MR, a planar layout described below is repeatedly arranged in the Y direction.

Each slit SLT has, for example, a structure in which an insulating member is embedded. Each slit SLT insulates interconnects (for example, the word lines WL0 to WL7 and the select gate lines SGD and SGS) adjacent via the slit SLT. Each slit SLT has a portion that is provided to extend along the X direction and that crosses the memory region MR and the hookup regions HR1 and HR2, along the X direction. The slits SLT are arranged in the Y direction. The regions that are delimited by the slits SLT correspond to the blocks BLK.

Each slit SHE has, for example, a structure in which an insulating member is embedded. Each slit SHE insulates select gate lines SGD adjacent via the slit SHE. Each slit SHE has a portion that is provided so as to extend along the X direction and that crosses the memory region MR. The slits SHE are arranged in the Y direction. In this example, three slits SHE are arranged between adjacent slits SLT. A plurality of regions partitioned by the slits SLT and SHE correspond to the string units SU0 to SU3, respectively.

Each memory pillar MP functions as, for example, one NAND string NS. The memory pillars MP are arranged in, for example, 19 rows in a staggered manner in a region between two adjacent slits SLT. Further, the respective slits SHE overlap the fifth row of the memory pillars MP, the tenth row of the memory pillars M, and the fifteenth row of the memory pillars MP, from the upper side of the drawing.

Each of the bit lines BL has a portion that is provided to extend along the Y direction, and that crosses a region where the blocks BLK are provided, along the Y direction. The bit lines BL are arranged in the X direction. Each bit line BL is arranged to overlap at least one memory pillar MP for each string unit SU. In this example, two bit lines BL overlap each memory pillar MP.

Each contact CV is provided between one bit line BL among the bit lines BL overlapping the memory pillar MP, and the memory pillar MP. The contact CV electrically connects the memory pillar MP and the bit line BL. Note that illustration of the contact CV between the memory pillar MP overlapping the slit SHE and the bit line BL is omitted.

### (Cross-Sectional Structure of the Memory Cell Array 503)

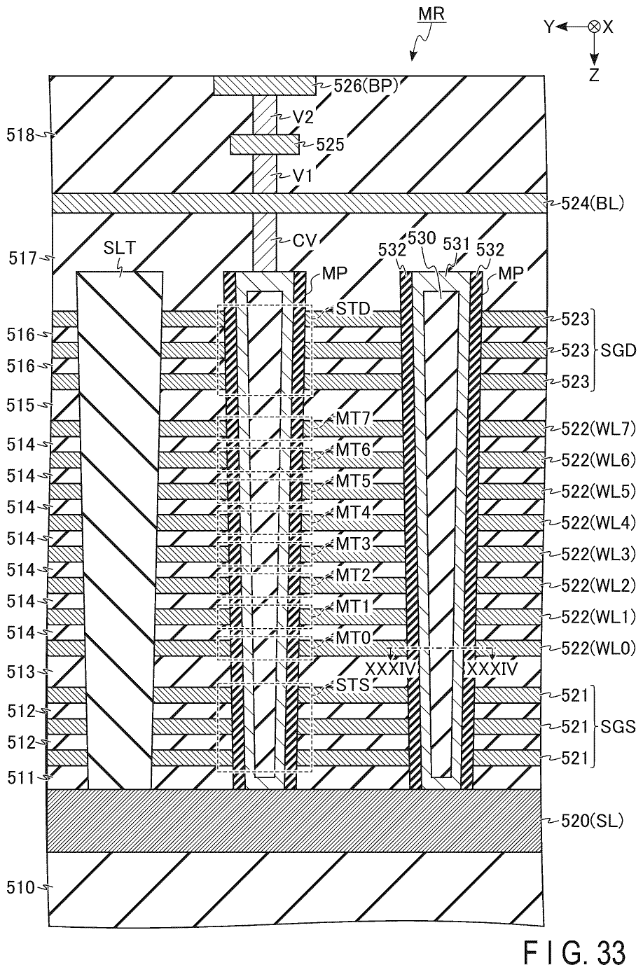

FIG. 33 is a cross-sectional view showing an example of a cross-sectional structure of the memory cell array 503 included in the memory device 500 according to the third embodiment. FIG. 33 shows a cross section along the Y direction that includes memory pillars MP and a slit SLT in the memory region MR. As shown in FIG. 33, the memory device 500 includes insulating layers 510 to 518, conductive layers 520 to 526, and contacts V1 and V2.

The insulating layer 510 is, for example, located in the lowermost layer of the memory chip MC. In the layer in which the insulating layer 510 is formed, interconnects used to connect the conductive layer 520 and the pad PD may be provided. A conductive layer 520 and an insulating layer 511 are sequentially provided on the insulating layer 510. Conductive layers 521 and insulating layers 512 are alternately provided on the insulating layer 511. An insulating layer 513 is provided on the uppermost conductive layer 521. Conductive layers 522 and insulating layers 514 are alternately provided on the insulating layer 513. An insulating layer 515 is provided on the uppermost conductive layer 522. Conductive layers 523 and insulating layers 516 are alternately provided on the insulating layer 515. An insulating layer 517, a conductive layer 524, and an insulating layer 518 are sequentially provided on the uppermost conductive layer 523. The insulating layer 518 includes contacts V1 and V2 and conductive layers 525 and 526. The contact V1 connects the conductive layer 524 and the conductive layer 525. The contact V2 connects the conductive layer 525 and the conductive layer 526.

Each of the conductive layers 520, 521, 522, and 523 has, for example, a portion formed in a plate shape spreading along the XY plane. The conductive layer 524 has, for example, a portion formed in a line shape extending in the Y direction. The conductive layers 520, 521, and 523 are used as a source line SL, a select gate line SGS, and a select gate line SGD, respectively. The conductive layers 522 are used as word lines WL0 to WL7 in this order from the bottom. The conductive layer 524 is used as a bit line BL. The conductive layer 526 is used as a bonding pad BP of the memory chip MC. The conductive layer 526 contains, for example, copper.

The slit SLT has a portion spreading along the XZ plane, and divides the insulating layers 511 to 516 and the conductive layers 521 to 523. Each memory pillar MP is provided to extend along the Z direction, and penetrates the insulating layers 511 to 516 and the conductive layers 521 to 523. Each memory pillar MP includes, for example, a core member 530, a semiconductor layer 531, and a stacked film 532. The core member 530 is an insulator provided to extend along the Z direction. The semiconductor layer 531 covers the core member 530. A lower portion of the semiconductor layer 531 is in contact with the conductive layer 520. The stacked film 532 covers the side surface of the semiconductor layer 531. A contact CV is provided on the semiconductor layer 531. The semiconductor layer 531 is electrically connected to the conductive layer 524 via the contact CV. Portions where the memory pillar MP and the conductive layers 521 intersect each other function as a select transistor STS. A portion where the memory pillar MP and the conductive layer 522 intersect each other functions as a memory cell transistor MT. Portions where the memory pillar MP and the conductive layers 523 intersect each other function as a select transistor STD.

### (Cross-Sectional Structure of Memory Pillar MP)

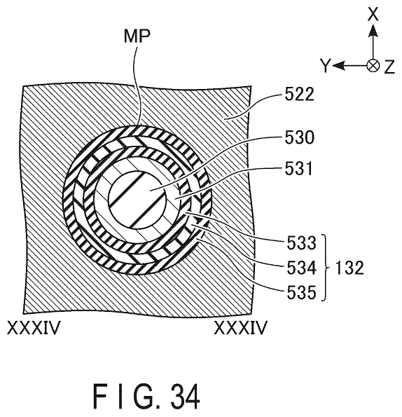

FIG. 34 is a cross-sectional view taken along line XXXIV-XXXIV of FIG. 33, showing an example of a cross-sectional structure of the memory pillar MP included in the memory device 500 according to the third embodiment. FIG. 34 shows a cross section parallel to the X direction and the Y direction that includes the memory pillar MP and the conductive layer 522. As shown in FIG. 34, the stacked film 532 includes a tunnel insulating film 533, an insulating film 534, and a block insulating film 535. The core member 530 is provided in a center portion of the memory pillar MP. The semiconductor layer 531 surrounds the side surface of the core member 530. The tunnel insulating film 533 surrounds the side surface of the semiconductor layer 531. The insulating film 534 surrounds the side surface of the tunnel insulating film 533. The block insulating film 535 surrounds the side surface of the insulating film 534. The conductive layer 522 surrounds the side surface of the block insulating film 535. The semiconductor layer 531 is used as a channel (current path) of the memory cell transistors MT0 to MT7 and the select transistors STD and STS. Each of the tunnel insulating film 533 and the block insulating film 535 contains, for example, silicon dioxide (SiO₂). The insulating film 534 is used as a charge storage layer of the memory cell transistor MT, and contains, for example, silicon nitride (SiN).

### <3-3-2> Cross-Sectional Structure of the Memory Device 500

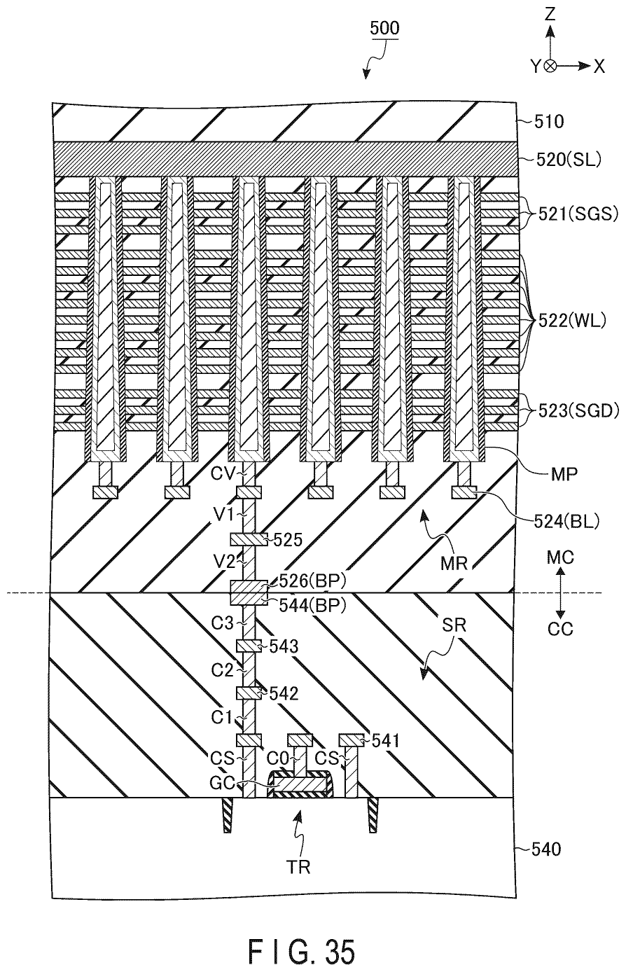

FIG. 35 is a cross-sectional view showing an example of a cross-sectional structure of the memory device 500 according to the third embodiment. FIG. 35 shows a cross section including the memory region MR and the sense amplifier region SR, that is, a cross section including the memory chip MC and the CMOS chip CC. As shown in FIG. 35, in the sense amplifier region SR, the memory device 500 includes, for example, a semiconductor substrate 540, conductive layers GC and 541 to 544, and contacts CS and C0 to C3.

The semiconductor substrate 540 is a substrate used to form the CMOS chip CC. The semiconductor substrate 540 includes a plurality of well regions (not illustrated). For example, a transistor TR is formed in each of the plurality of well regions. A conductive layer GC is provided on the semiconductor substrate 540 via a gate insulating film. The conductive layer GC in the sense amplifier region SR is used as a gate electrode of the transistor TR included in the sense amplifier module 506. The contact C0 is provided on the conductive layer GC. Two contacts CS are provided on the semiconductor substrate 540 in correspondence with the source and the drain of the transistor TR.

Each contact CS is connected to the associated conductive layer 541. The contact C0 is connected to the associated conductive layer 541. A conductive layer 541 is connected to a bonding pad BP (a conductive layer 544) of the CMOS chip CC via a contact C1, a conductive layer 542, a contact C2, a conductive layer 543, and a contact C3. The conductive layer 544 in the sense amplifier region SR is bonded to a conductive layer 526 in the memory region MR (that is, a bonding pad BP of the memory chip MC) that is placed to face the conductive layer 544. Each conductive layer 544 in the sense amplifier region SR is electrically connected to one bit line BL. The conductive layer 544 contains, for example, copper. The number of interconnect layers of each of the memory chip MC and the CMOS chip CC can be changed according to the configuration of the memory device 500, as appropriate.

### <3-4> Advantageous Effects of the Third Embodiment

As described hereinabove, in the memory device 500, the memory chip MC includes a memory cell array 503, and the CMOS chip CC includes a CMOS circuit. The memory chip MC is used as an upper wafer UW in the bonding process, and the CMOS chip CC is used as a lower wafer LW in the bonding process, for example. As described above, the memory chip MC and the CMOS chip are greatly different in the structure of the circuit to be formed. In particular, the memory chip MC has a tendency that the XY difference of wafer magnification components increases with the formation of the memory cell array 503. Therefore, the yield may be reduced due to the influence of the XY differences of wafer magnification components of the bonding surfaces of the memory chip MC and the CMOS chip CC.

Thus, it can be attempted to apply the bonding method and the method for manufacturing a semiconductor device described in the first and second embodiments to the manufacturing of the memory device 500 according to the third embodiment. That is, the accuracy of overlay of the memory chip MC and the CMOS chip CC in the memory device 500 according to the third embodiment can be improved by a process in which correction to the XY difference of wafer magnification components by temperature adjustment of the lower stage 230 is applied during the bonding process of the memory chip MC and the CMOS chip CC. As a result, the yield of memory devices 500 according to the third embodiment can be improved by applying the method for manufacturing a semiconductor device according to the first or second embodiment.

The object to which the bonding method and the method for manufacturing a semiconductor device described in the first embodiment and the second embodiment are applied is not limited to the memory device 500. The object to which the bonding method and the method for manufacturing a semiconductor device described in the first embodiment and the second embodiment are applied needs only to be a semiconductor device having a bonding structure.

### <4> Modification Examples, Etc.

Although the above embodiments describe, as an example, a case where a heater 44 is provided in the lower stage 230 of the bonding apparatus 2, the configuration is not limited thereto. It is sufficient for the lower stage 230 to be configured to be temperature-adjustable. The lower stage 230 may be configured to be adjustable to a temperature lower than room temperature RT. Also in such a case, by temperature adjustment of the lower stage 230 (the body part 40), the bonding apparatus 2 can correct the XY differences of wafer magnification components in the lower wafer LW and the upper wafer UW to be bonded. Although the second embodiment describes, as an example, a case where the bonding apparatus 2 executes the process shown in FIG. 27, the scheme is not limited thereto. The process shown in FIG. 27 can be executed by any apparatus that includes a temperature-adjustable wafer stage and that can perform alignment measurement. In this case, the wafer stage included in the apparatus that executes the process shown in FIG. 27 is preferably a similar configuration to the lower stage 230 of the bonding apparatus 2 (the stage pins 42, the heater 44, etc.).

In the above embodiments, the flowcharts used to describe the bonding method and the method for manufacturing a semiconductor device are merely examples. In the operations described using the flowcharts, the order of processes are interchangeable within a permissible range, other processes may be added, or some of the processes may be omitted. As the control devices 10 and 20, an MPU (micro-processing unit), an ASIC (application-specific integrated circuit), an FPGA (field-programmable gate array), or the like may be used instead of a CPU. Each piece of the processes described in the above embodiments may be implemented by dedicated hardware. The processes described in the above embodiments may be a mixture of processes executed by software and processes executed by hardware, or may be either one of such types of processes.

The circuit configuration, planar layout, and cross-sectional structure of the memory device 500 described in the third embodiment can be changed according to the design of the memory device 500, as appropriate. For example, although the third embodiment describes, as an example, a case where a memory chip MC is provided on a CMOS chip CC, also a configuration in which a CMOS chip CC is provided on a memory chip MC is possible. That is, a CMOS chip CC may be allocated to the upper wafer UW, and a memory chip MC may be allocated to the lower wafer LW. In the present specification, “connection” refers to being electrically connected, and does not exclude being connected via another element. “Electrically connected” may be connection via an insulator as long as operations similar to those in a case of being electrically connected can be performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A bonding apparatus, comprising:
a first stage including a body part, a plurality of stage pins provided on an upper portion of the body part, and a heater that heats the body part, the first stage being configured to be able to hold a first substrate by using the stage pins;
a second stage configured to be able to hold a second substrate; and
a processor configured to control the first stage and the second stage to execute bonding process of bonding the first substrate and the second substrate, wherein
the first stage has, in a planar view, a center portion including a center of the first stage and an outer peripheral portion located on an outer periphery of the center portion,
the stage pins include a plurality of first pins arranged in a first direction, the plurality of first pins being configured such that at least one of an area and a length is different between a first pin located in the center portion of the first stage and a first pin located in the outer peripheral portion, and
the stage pins include a plurality of second pins arranged in a second direction different from the first direction, the plurality of second pins being configured such that at least one of the area and the length is substantially the same between a second pin located in the center portion of the first stage and a second pin located in the outer peripheral portion.

2. The bonding apparatus according to claim 1, wherein
the processor is further configured to, in the bonding process, adjust a temperature of the heater based on a third difference between a first difference of magnification components between the first direction and the second direction of the first substrate and a second difference of magnification components between the first direction and the second direction of the second substrate.

3. The bonding apparatus according to claim 1, wherein
the first stage is configured such that a ratio of an area where the first substrate and the stage pins are in contact decreases from the center portion toward the outer peripheral portion of the first stage in the first direction.

4. The bonding apparatus according to claim 3, wherein
the first stage is further configured such that a pitch between adjacent two stage pins of the stage pins arranged in the first direction increases from the center portion toward the outer peripheral portion of the first stage.

5. The bonding apparatus according to claim 4, wherein
the pitch between adjacent two stage pins of the stage pins arranged in the first direction is in a range of 2000 to 20000 μm.

6. The bonding apparatus according to claim 3, wherein
the first stage is further configured such that a diameter of an upper surface of each of the stage pins arranged in the first direction decreases from the center portion toward the outer peripheral portion of the first stage.

7. The bonding apparatus according to claim 6, wherein
a diameter of each of the stage pins arranged in the first direction is in a range of 100 to 1000 μm.

8. The bonding apparatus according to claim 1, wherein
the first stage is further configured such that a height of each of the stage pins arranged in the first direction increases from the center portion toward the outer peripheral portion of the first stage.

9. The bonding apparatus according to claim 8, wherein
the height of each of the stage pins arranged in the first direction is in a range of 100 to 2000 μm.

10. The bonding apparatus according to claim 2, further comprising:
a first measuring device capable of measuring a plurality of first alignment marks arranged on the first substrate held by the first stage; and
a second measuring device capable of measuring a plurality of second alignment marks arranged on the second substrate held by the second stage, wherein
the processor is further configured to calculate the first difference based on a result of measurement of the first alignment marks by the first measuring device, and calculate the second difference based on a result of measurement of the second alignment marks by the second measuring device.

11. The bonding apparatus according to claim 2, further comprising
a first measuring device capable of measuring a plurality of first alignment marks arranged on the first substrate held by the first stage, wherein
the processor is further configured to:
execute, at a plurality of temperatures, a combination of adjusting the temperature of the heater and measuring the first alignment marks;
calculate the first difference of magnification components of the first substrate between the first direction and the second direction based on a result of measurement of the first alignment marks in correspondence with each of the temperatures;
create a relational expression between the first difference and the temperature of the heater based on a result of calculation of the first difference at each of the temperatures; and
select an optimum temperature of the heater based on the relational expression.

12. A bonding method using a bonding apparatus including: a first stage including a body part, a plurality of stage pins provided on an upper portion of the body part, and a heater that heats the body part, the first stage being configured to be able to hold a first substrate by using the stage pins; and a second stage configured to be able to hold a second substrate, wherein the first stage has, in a planar view, a center portion including a center of the first stage and an outer peripheral portion located on an outer periphery of the center portion, the stage pins include a plurality of first pins arranged in a first direction, the plurality of first pins being configured such that at least one of an area and a length is different between a first pin located in the center portion of the first stage and a first pin located in the outer peripheral portion, and the stage pins include a plurality of second pins arranged in a second direction different from the first direction, the plurality of second pins being configured such that at least one of the area and the length is substantially the same between a second pin located in the center portion of the first stage and a second pin located in the outer peripheral portion, the bonding method comprising:
calculating a first difference of magnification components between the first direction and the second direction of the first substrate;
calculating a second difference of magnification components between the first direction and the second direction of the second substrate;
adjusting a temperature of the body part based on a third difference between the first difference and the second difference and causing the first stage to hold the first substrate;
causing the second stage to hold the second substrate; and
controlling the first stage and the second stage to bond the first substrate and the second substrate.

13. The bonding method according to claim 12, further comprising:
adjusting the heater at a plurality of different temperatures and bonding a plurality of first substrates individually to a plurality of second substrates to produce a plurality of bonded substrates;
in each of the bonded substrates, measuring overlap of the first substrate and the second substrate and calculating a fourth difference of magnification components of the bonded substrate between the first direction and the second direction;
creating a relational expression between the fourth difference and a temperature of the heater based on a result of calculation of the fourth difference at each of the temperatures; and
adjusting the temperature of the heater based on the relational expression.

14. The bonding method according to claim 12, further comprising:
executing, at a plurality of temperatures, a combination of adjusting a temperature of the heater and measuring a plurality of alignment marks arranged on the first substrate held by the first stage;
calculating the first difference of magnification components of the first substrate between the first direction and the second direction based on a result of measurement of the alignment marks in correspondence with each of the temperatures;
creating a relational expression between the first difference and the temperature of the heater based on a result of calculation of the first difference at each of the temperatures; and
adjusting the temperature of the heater based on the relational expression.

15. A method for manufacturing a semiconductor device, the method using a bonding apparatus including: a first stage including a body part, a plurality of stage pins provided on an upper portion of the body part, and a heater that heats the body part, the first stage being configured to be able to hold a first substrate by using the stage pins; and a second stage configured to be able to hold a second substrate, wherein the first stage has, in a planar view, a center portion including a center of the first stage and an outer peripheral portion located on an outer periphery of the center portion, the stage pins include a plurality of first pins arranged in a first direction, the plurality of first pins being configured such that at least one of an area and a length is different between a first pin located in the center portion of the first stage and a first pin located in the outer peripheral portion, and the stage pins include a plurality of second pins arranged in a second direction different from the first direction, the plurality of second pins being configured such that at least one of the area and the length is substantially the same between a second pin located in the center portion of the first stage and a second pin located in the outer peripheral portion, the method comprising:
calculating a first difference of magnification components between the first direction and the second direction of the first substrate;
calculating a second difference of magnification components between the first direction and the second direction of the second substrate;
adjusting a temperature of the heater based on a third difference between the first difference and the second difference and causing the first stage to hold the first substrate;
causing the second stage to hold the second substrate; and
controlling the first stage and the second stage to bond the first substrate and the second substrate.

16. The method for manufacturing a semiconductor device according to claim 15, further comprising:
adjusting the heater at a plurality of different temperatures and bonding a plurality of first substrates individually to a plurality of second substrates to produce a plurality of bonded substrates;
in each of the bonded substrates, measuring overlap of the first substrate and the second substrate and calculating a fourth difference of magnification components of the bonded substrate between the first direction and the second direction;
creating a relational expression between the fourth difference and the temperature of the heater based on a result of calculation of the fourth difference at each of the temperatures; and
adjusting the temperature of the heater based on the relational expression.

17. The method for manufacturing a semiconductor device according to claim 15, further comprising:
executing, at a plurality of temperatures, a combination of adjusting the temperature of the heater and measuring a plurality of alignment marks arranged on the first substrate held by the first stage;
calculating the first difference of magnification components of the first substrate between the first direction and the second direction based on a result of measurement of the alignment marks in correspondence with each of the temperatures;
creating a relational expression between the first difference and the temperature of the heater based on a result of calculation of the first difference at each of the temperatures; and
adjusting the temperature of the heater based on the relational expression.
